(19) United States
(12) Patent Application Publication
(10) Pub. No.: US 2021/0288058 A1
(43) Pub. Date: Sep. 16, 2021

(54) SEMICONDUCTOR MEMORY DEVICE

(71) Applicant: Kioxia Corporation, Tokyo (JP)

(72) Inventors: Takahito NISHIMURA, Kuwana (JP); Takuya NISHIKAWA, Yokkaichi (JP); Shihoko ASAI, Yokkaichi (JP)

(73) Assignee: Kioxia Corporation, Tokyo (JP)

(21) Appl. No.: 17/152,902

(22) Filed: Jan. 20, 2021

(30) Foreign Application Priority Data
Mar. 16, 2020 (JP) 2020-044896

(51) Int. Cl. H01L 27/11565; H01L 27/11575; H01L 27/11582

(52) U.S. Cl. CPC H01L 27/11565; H01L 27/11582; H01L 27/11575

(57) ABSTRACT

A semiconductor memory device according to an embodiment includes a substrate, first members, first conductive layers, and first and second pillars. The substrate includes first and second areas, and block areas. The first conductive layers are split by the first members. The first pillars are provided in an area in which the first area and the block areas overlap. The second pillars are provided in an area in which the second area and the block areas overlap. The second area includes a first sub-area in which the second pillars are periodically arranged in an area that overlaps at least one block area in the block areas. In the first sub-area, at least one second pillar is omitted from the second pillars that are periodically arranged.

### CROSS-REFERENCE TO RELATED APPLICATIONS

This application is based upon and claims the benefit of priority from Japanese Patent Application No. 2020-044896, filed Mar. 16, 2020, the entire contents of which are incorporated herein by reference.

### FIELD

Embodiments described herein relate generally to a semiconductor memory device.

### BACKGROUND

A NAND-type flash memory capable of storing data in a nonvolatile manner is known.

### BRIEF DESCRIPTION OF THE DRAWINGS

FIG. 1 is a block diagram showing an example of an overall configuration of a semiconductor memory device according to an embodiment.

FIG. 2 is a circuit diagram showing an example of a circuit configuration of a memory cell array included in the semiconductor memory device according to the embodiment.

FIG. 3 is a plan view showing an example of a planar layout of the memory cell array included in the semiconductor memory device according to the embodiment.

FIG. 4 is a plan view showing an example of a detailed planar layout of a memory area in the memory cell array included in the semiconductor memory device according to the embodiment.

FIG. 5 is a cross-sectional view taken along line V-V of FIG. 4, showing an example of a cross-sectional structure of the memory area of a memory cell array included in the semiconductor memory device according to the embodiment.

FIG. 6 is a cross-sectional view taken along line VI-VI of FIG. 5, showing an example of a cross-sectional structure of a memory pillar in the semiconductor memory device according to the embodiment.

FIG. 7 is a plan view showing an example of a planar layout of a hookup area of the memory cell array included in the semiconductor memory device according to the embodiment.

FIG. 8 is a cross-sectional view taken along line VIII-VIII of FIG. 7, showing an example of a cross-sectional structure of the hookup area of the memory cell array included in the semiconductor memory device according to the embodiment.

FIG. 9 is a plan view showing an example of a planar layout of a contact area of the memory cell array included in the semiconductor memory device according to the embodiment.

FIG. 10 is a cross-sectional view showing an example of a cross-sectional structure of a contact area of the memory cell array included in the semiconductor memory device according to the embodiment.

FIG. 11 is a cross-sectional view taken along line XI-XI of FIG. 10, showing an example of a cross-sectional structure of a contact area of the memory cell array included in the semiconductor memory device according to the embodiment.

FIG. 12 is a flowchart showing an example of a method of manufacturing the semiconductor memory device according to the embodiment.

FIG. 13 is a plan view showing an example of a planar layout of the semiconductor memory device in the course of manufacturing according to the embodiment.

FIG. 14 is a cross-sectional view showing an example of a cross-sectional structure of the semiconductor memory device in the course of manufacturing according to the embodiment.

FIG. 15 is a plan view showing an example of a planar layout of the semiconductor memory device in the course of manufacturing according to the embodiment.

FIGS. 16, 17 and 18 are cross-sectional views showing an example of a cross-sectional structure of the semiconductor memory device in the course of manufacturing according to the embodiment.

FIG. 19 is a plan view showing an example of a planar layout of the semiconductor memory device in the course of manufacturing according to the embodiment.

FIG. 20 is a cross-sectional view showing an example of a cross-sectional structure of the semiconductor memory device in the course of manufacturing according to the embodiment.

FIG. 21 is a plan view showing an example of a planar layout of the semiconductor memory device in the course of manufacturing according to the embodiment.

FIGS. 22 and 23 are cross-sectional views showing an example of a cross-sectional structure of the semiconductor memory device in the course of manufacturing according to the embodiment.

FIG. 24 is a plan view showing an example of a planar layout of the semiconductor memory device in the course of manufacturing according to the embodiment.

FIGS. 25 and 26 are cross-sectional views showing an example of a cross-sectional structure of the semiconductor memory device in the course of manufacturing according to the embodiment.

FIG. 27 is a schematic diagram showing an example of a length measurement method in a manufacturing process of a semiconductor memory device according to a comparative example of the embodiment.

FIG. 28 is a schematic diagram showing an example of a length measurement method in a manufacturing process of the semiconductor memory device according to the embodiment.

FIG. 29 is a plan view showing an example of arrangement of a unique pattern in a semiconductor memory device according to a first modification of the embodiment.

FIG. 30 is a plan view showing an example of a configuration of a unique pattern in a semiconductor memory device according to a second modification of the embodiment.

FIG. 31 is a plan view showing an example of arrangement of unique patterns in a semiconductor memory device according to a third modification of the embodiment.

FIG. 32 is a cross-sectional view showing an example of a cross-sectional structure of a memory cell array included in a semiconductor memory device according a fourth modification of the embodiment.

### DETAILED DESCRIPTION

In general, according to one embodiment, a semiconductor memory device includes a substrate, a plurality of first members, a plurality of first conductive layers, a plurality of first pillars, and a plurality of second pillars. The substrate includes a first area, a second area, and a plurality of block areas. The first area and the second area are arranged in a first direction. The block areas are provided to extend in the first direction. The block areas are arranged in a second direction intersecting the first direction. The plurality of first members are provided to extend in the first direction. Each of the first members is arranged at a boundary portion between the block areas. The plurality of first conductive layers are arranged in a third direction intersecting the first and second directions and provided to be separated from one another. The first conductive layers are split by the first members. The plurality of first pillars are provided in an area in which the first area and the block areas overlap, to penetrate the first conductive layers in the third direction. The plurality of second pillars are provided in an area in which the second area and the block areas overlap, to penetrate the first conductive layers in the third direction. The second area includes a first sub-area in which the second pillars are periodically arranged in an area that overlaps at least one block area in the block areas. In the first sub-area, at least one second pillar is omitted from the second pillars that are periodically arranged.

Hereinafter, embodiments will be described with reference to the accompanying drawings. The embodiments exemplify a device and method for embodying the technical idea of the invention. The drawings are schematic or conceptual, and the dimensions, ratios, etc. in the drawings are not always the same as the actual ones. The technical idea of the present invention is not specified by the shapes, structures, arrangements, etc. of the components.

In the description that follows, components having substantially the same functions and configurations will be denoted by the same reference symbols. A numeral following letters constituting a reference symbol is used to distinguish between components referred to by reference symbols including the same letters and having the same configuration. If components represented by reference symbols including the same letters need not be distinguished, such components are assigned reference symbols including only the same letters.

### Embodiment

Hereinafter, a semiconductor memory device 1 according to an embodiment will be described.

### [1] Configuration of Semiconductor Memory Device 1

[1-1] Overall Configuration of Semiconductor Memory Device 1

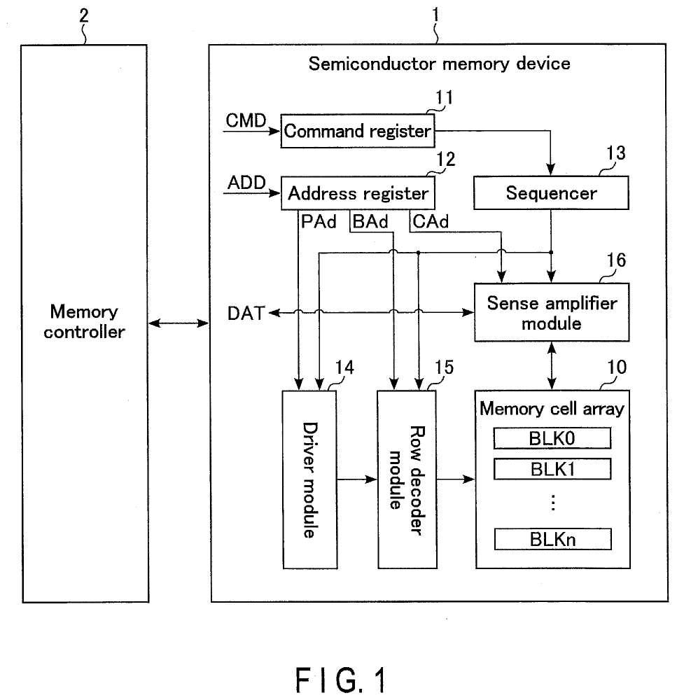

FIG. 1 shows a configuration example of a semiconductor memory device 1 according to an embodiment. The semiconductor memory device 1 is, for example, a NAND flash memory capable of storing data in a non-volatile manner, and is controlled by an external memory controller 2.

As shown in FIG. 1, the semiconductor memory device 1 includes, for example, a memory cell array 10, a command register 11, an address register 12, a sequencer 13, a driver module 14, a row decoder module 15, and a sense amplifier module 16.

The memory cell array 10 includes a plurality of blocks BLK0 to BLKn (where n is an integer equal to or greater than 1). The block BLK is a set of a plurality of memory cells capable of storing data in a non-volatile manner, and is used as, for example, a unit of data erasure. A plurality of bit lines and a plurality of word lines are provided in the memory cell array 10. Each memory cell is associated with, for example, a single bit line and a single word line. A detailed configuration of the memory cell array 10 will be described later.

The command register 11 stores a command CMD received by the semiconductor memory device 1 from the memory controller 2. The command CMD includes an instruction to cause the sequencer 13 to perform, for example, a read operation, a write operation, an erase operation, etc.

The address register 12 stores address information ADD received by the semiconductor memory device 1 from the memory controller 2. The address information ADD contains, for example, a block address BAd, a page address PAd, and a column address CAd. The block address BAd, the page address PAd, and the column address CAd are used to respectively select, for example, a block BLK, a word line, and a bit line.

The sequencer 13 controls the entire operation of the semiconductor memory device 1. For example, the sequencer 13 controls the driver module 14, the row decoder module 15, and the sense amplifier module 16, etc., based on the command CMD stored in the command register 11, to perform a read operation, a write operation, an erase operation, etc.

The driver module 14 generates voltages used in a read operation, a write operation, an erase operation, etc. Based on, for example, the page address PAd stored in the address register 12, the driver module 14 applies the generated voltage to a signal line corresponding to a selected word line.

Based on the block address BAd stored in the address register 12, the row decoder module 15 selects a corresponding block BLK in the memory cell array 10. Thereafter, the row decoder module 15 transfers, for example, the voltage applied to the signal line corresponding to the selected word line to the selected word line in the selected block BLK.

In a write operation, the sense amplifier module 16 applies a desired voltage to each bit line in accordance with write data DAT received from the memory controller 2. In a read operation, the sense amplifier module 16 determines data stored in a memory cell based on the voltage of the corresponding bit line, and transfers the determination result to the memory controller 2 as read data DAT.

The above-described semiconductor memory device 1 and memory controller 2 in combination may configure a single semiconductor device. Examples of such semiconductor devices include a memory card such as an SD™ card, a solid state drive (SSD), etc.

[1-2] Circuit Configuration of Memory Cell Array 10

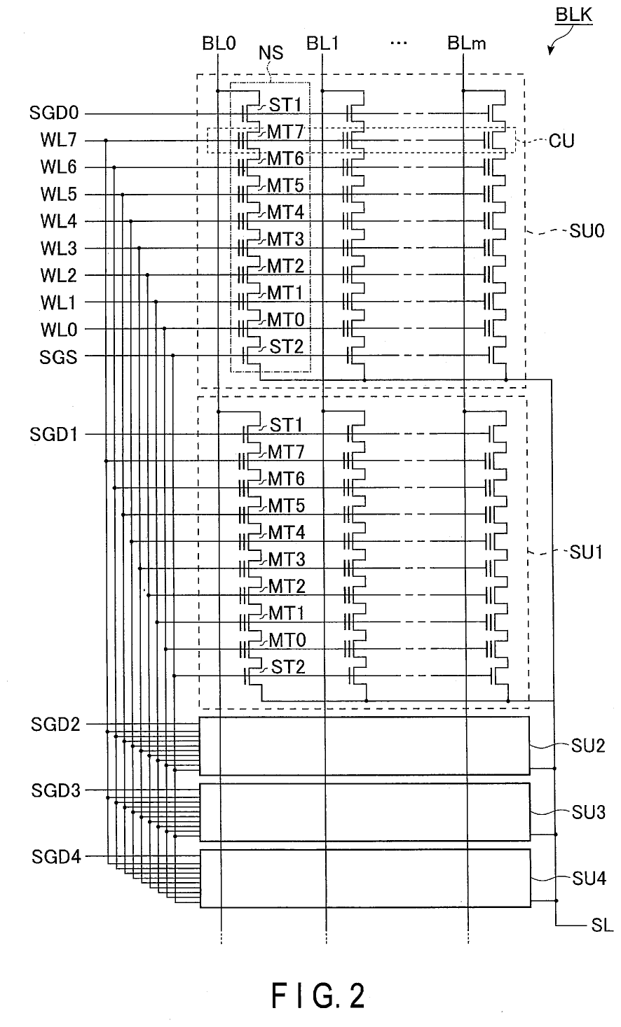

FIG. 2 shows an example of a circuit configuration of the memory cell array 10 included in the semiconductor memory device 1 according to the embodiment, illustrating one of a plurality of blocks BLK included in the memory cell array 10. As shown in FIG. 2, each block BLK includes, for example, five string units SU0 to SU4.

Each string unit SU includes a plurality of NAND strings NS that are respectively associated with bit lines BL0 to BLm (where m is an integer equal to or greater than 1). Each NAND string NS includes, for example, memory cell transistors MT0 to MT7 and select transistors ST1 and ST2. Each memory cell transistor MT includes a control gate and a charge storage layer, and stores data in a non-volatile manner. Each of the select transistors ST1 and ST2 is used to select a string unit SU in various operations.

In each NAND string NS, memory cell transistors MT0 to MT7 are coupled in series. A drain of the select transistor ST1 is coupled to a corresponding bit line BL. A source of the select transistor ST1 is coupled to one end of a set of memory cell transistors MT0 to MT7 coupled in series. A drain of the select transistor ST2 is coupled to the other end of the set of memory cell transistors MT0 to MT7 coupled in series. A source of the select transistor ST2 is coupled to a source line SL.

Control gates of sets of memory cell transistors MT0 to MT7 in the same block BLK are respectively coupled to the word lines WL0 to WL7. Gates of select transistors ST1 in the string unit SU0 are coupled to a select gate line SGD0. Gates of select transistors ST1 in the string unit SU1 are coupled to a select gate line SGD1. Gates of select transistors ST1 in the string unit SU2 are coupled to a select gate line SGD2. Gates of select transistors ST1 in the string unit SU3 are coupled to a select gate line. SGD3. Gates of select transistors ST1 in the string unit SU4 are coupled to a select gate line SGD4. Gates of the select transistors ST2 are coupled to a select gate line SGS.

Different column addresses are respectively assigned to the bit lines BL0 to BLm. The bit line BL is shared among NAND strings NS in different blocks BLK to which the same column address is assigned. A set of word lines WL0 to WL7 is provided for each block BLK. The source line SL is shared among, for example, a plurality of blocks BLK.

A set of memory cell transistors MT coupled to a common word line WL in a single string unit SU is referred to as, for example, a “cell unit CU”. For example, the storage capacity of a cell unit CU including memory cell transistors MT, which individually store 1-bit data, is defined as “1-page data”. A cell unit CU may have a storage capacity of 2 or more pages of data, according to the number of bits of data stored in the memory cell transistor MT.

The circuit configuration of the memory cell array 10 included in the semiconductor memory device 1 according to the embodiment is not limited to the above-described configuration. The number of string units SU included in each block BLK and the number of each of the memory cell transistors MT and the select transistors ST1 and ST2 included in each NAND string NS may be any number.

[1-3] Structure of Memory Cell Array 10

Hereinafter, an example of a structure of the semiconductor memory device 1 according to the embodiment will be described. In the drawings that will be referred to hereinafter, “X direction” corresponds to the direction in which the word lines WL extend, “Y direction” corresponds to the direction in which the bit lines BL extend, and “Z direction” corresponds to the direction vertical to the surface of the semiconductor substrate 20, which is used to form the semiconductor memory device 1. In planar views, hatching is applied, where necessary, for improved visibility. The hatching applied in the planar views does not necessarily relate to the material or characteristics of the hatched components. In cross-sectional views, the configurations are omitted, where not necessary, for improved visibility.

(Planar Layout of Memory Cell Array 10)

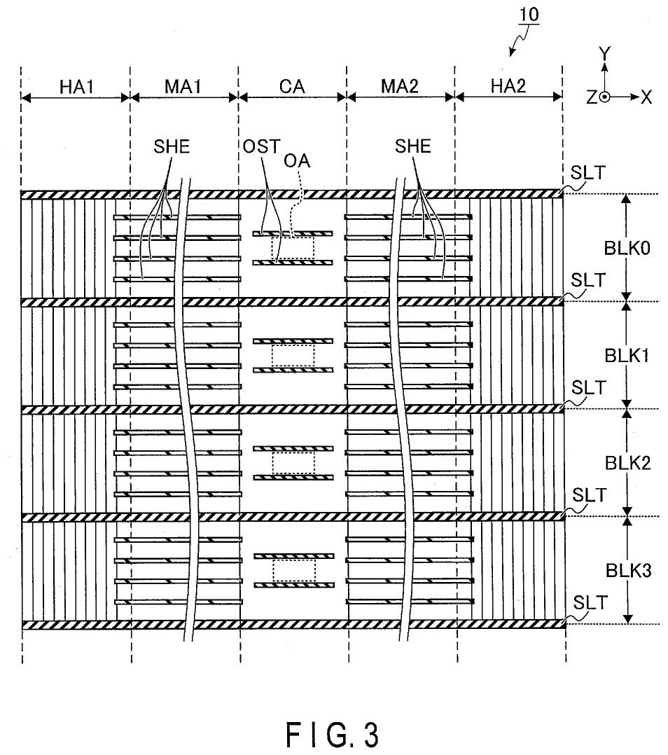

FIG. 3 shows an example of a planar layout of the memory cell array 10 included in the semiconductor memory device 1 according to the embodiment, in which an area corresponding to four blocks BLK0 to BLK3 are illustrated. As shown in FIG. 3, the memory cell array 10 in a planar layout is divided into, for example, memory areas MA1 and MA2, hookup areas HA1 and HA2, and a contact area CA, in the X direction. Also, the memory cell array 10 includes a plurality of slits SLT, SHE, and OST.

The memory areas MA1 and MA2 are arranged between the hookup areas HA1 and HA2. The contact area CA is arranged between the memory areas MA1 and MA2. Each of the memory areas MA1 and MA2 includes a plurality of NAND strings NS. Each of the hookup areas HA1 and HA2 includes a staircase structure of stacked interconnects (e.g., word lines WL and select gate lines SGD and SGS). A plurality of contacts for providing electrical connections between the stacked interconnects coupled to the NAND string NS and the row decoder module 15 are coupled to the staircase structure. The contact area CA includes a penetration contact that penetrates the stacked structure of the memory cell array 10.

The slits SLT, each of which includes a portion provided so as to extend along the X direction, are arranged in the Y direction. Each of the slits SLT intersects the memory areas MA1 and MA2, the hookup areas HA1 and HA2, and the contact area CA as viewed in the X direction. Each slit SLT has, for example, a structure in which an insulator or a plate-shaped contact is embedded inside, and splits interconnects that are adjacent to each other via the slit SLT (e.g., word lines WL0 to WL7 and select gate lines SGD and SGS).

The slits SHE are arranged in each of the memory areas MA1 and MA2. The slits SHE corresponding to the memory area MA1 are provided so as to intersect the memory area MA1, and are arranged in the Y direction. The slits SHE corresponding to the memory area MA2 are provided so as to intersect the memory area MA2, and are arranged in the Y direction. In the present example, four slits SHE are arranged between adjacent slits SLT. Each slit SHE has a structure in which an insulator is embedded inside. Each slit SHE splits interconnects (at least select gate lines SGD) that are adjacent to each other via the slit SHE.

The slits OST are arranged in the contact area CA. Each slit OST includes a portion provided so as to extend in the X direction. In the present example, two slits OST are arranged between adjacent slits SLT. Two slits OST are arranged between adjacent slits SLT so as to be separated from each other, and are arranged in the Y direction. Each slit OST has a structure in which an insulator is embedded inside. A penetration area OA in which a penetration contact is arranged is provided between two slits OST provided between adjacent slits SLT.

In the above-described planar layout of the memory cell array 10, each of the areas separated by the slits SLT corresponds to one block BLK. Also, each of the areas separated by the slits SLT and SHE corresponds to a single string unit SU. In the memory cell array 10, the layout shown in FIG. 3, for example, is repeatedly arranged in the Y direction.

The planar layout of the memory cell array 10 included in the semiconductor memory device 1 according to the embodiment is not limited to the above-described layout. The number of slits SHE arranged between adjacent slits SLT may be designed to be any number. The number of string units SU formed between adjacent slits SLT may be changed based on the number of the slits SHE arranged between adjacent slits SLT.

(Structure of Memory Cell Array 10 in Memory Area MA)

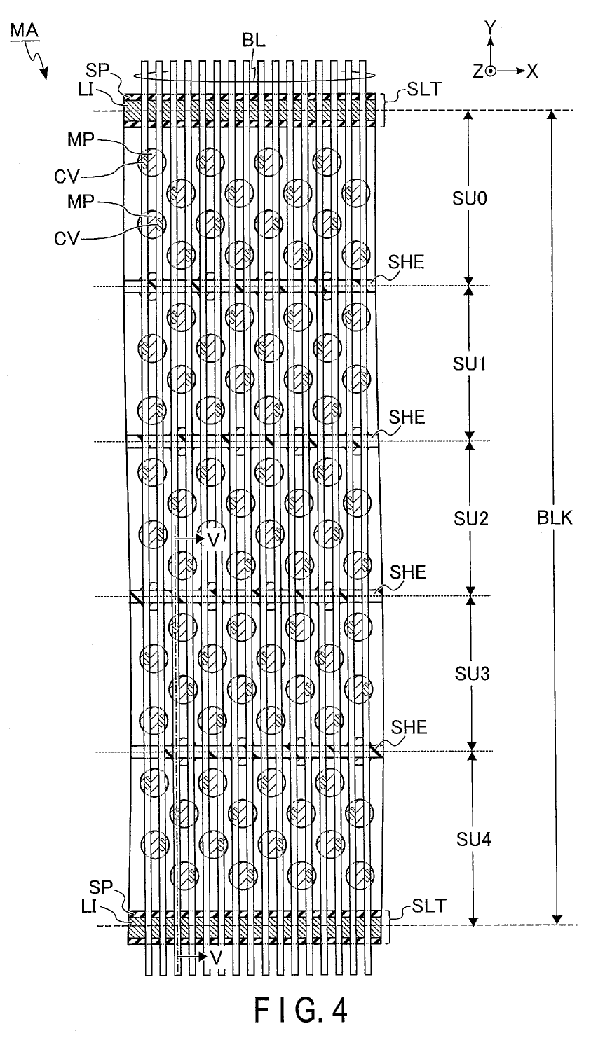

FIG. 4 shows an example of a detailed planar layout of a memory area MA of the memory cell array 10 included in the semiconductor memory device 1 according to the embodiment, illustrating an area including a single block BLK (i.e., string units SU0 to SU4). As shown in FIG. 4, the memory cell array 10 in the memory area MA includes a plurality of memory pillars MP, a plurality of contacts CV, and a plurality of bit lines BL. Each slit SLT includes a contact LI and a spacer SP.

Each memory pillar MP functions as, for example, a single NAND string NS. The memory pillars MP are in, for example, a 24-row staggered arrangement in an area between two adjacent slits SLT. The memory pillars MP in the fifth row, the memory pillars MP in the tenth row, the memory pillars MP in the fifteenth row, and the memory pillars MP in the twentieth row, counting from the top of the drawing, for example, overlap a single slit SHE.

The bit lines BL extend in the Y direction, and are arranged in the X direction. Each bit line BL is arranged so as to overlap at least one memory pillar MP in each string unit SU. In the present example, two bit lines BL overlap each memory pillar MP. A contact CV is provided between a memory pillar MP and one of the bit lines BL that overlap the memory pillar MP. Each memory pillar MP is electrically coupled to the corresponding bit line BL via a contact CV.

A contact CV between the bit line BL and the memory pillar MP which overlaps the slit SHE is omitted. In other words, a contact CV between the bit line BL and the memory pillar MP that is in contact with two different select gate lines SGD is omitted. The number and arrangement of the memory pillars MP, the slits SHE, etc. between adjacent slits SLT are not limited to the configuration described with reference to FIG. 4, and may be suitably varied. The number of bit lines BL that overlap each memory pillar MP may be designed to be any number.

The contact LI is a conductor which includes a portion that extends in the X direction. The spacer SP is an insulator that is provided on a side surface of the contact LI. The contact LI and a conductor that is adjacent to the contact LI in the Y direction are distanced and insulated by the spacer SP. The contact LI is used as, for example, part of the source line SL.

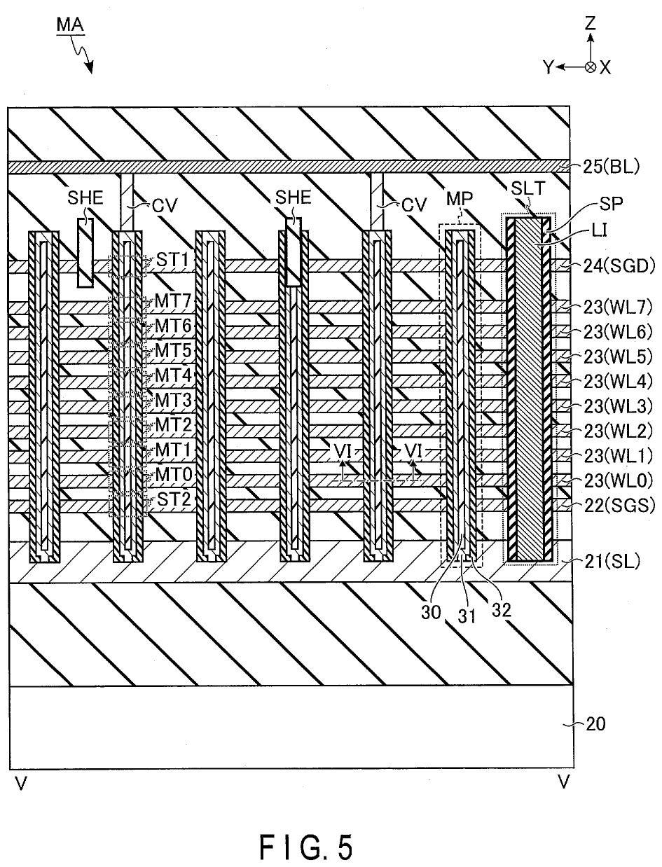

FIG. 5 is a cross-sectional view taken along line V-V of FIG. 4, showing an example of a cross-sectional structure of a memory area MA of the memory cell array 10 included in the semiconductor memory device 1 according to the embodiment. As shown in FIG. 5, the memory cell array 10 includes, for example, conductive layers 21 to 25. The conductive layers 21 to 25 are provided above a semiconductor substrate 20.

Specifically, a conductive layer 21 is provided above the semiconductor substrate 20, with an insulating layer interposed therebetween. In the insulating layer between the semiconductor substrate 20 and the conductive layer 21, circuits corresponding to, for example, the row decoder module 15, the sense amplifier module 16, etc. are provided, even though such circuits are not illustrated. The conductive layer 21 is formed, for example, in a plate shape extending along the XY plane, and is used as a source line SL. The conductive layer 21 contains, for example, phosphorous-doped silicon.

A conductive layer 22 is provided above the conductive layer 21, with an insulating layer interposed therebetween. The conductive layer 22 is formed in, for example, a plate-like shape extending along the XY plane, and is used as a select gate line SGS. The conductive layer 22 contains, for example, tungsten.

Insulating layers and conductive layers 23 are stacked in an alternating manner above the conductive layer 22. The conductive layers 23 are formed, for example, in a plate shape extending along the XY plane. The stacked conductive layers 23 are used as, in the order from the side of the semiconductor substrate 20, word lines WL0 to WL7. The conductive layers 23 contain, for example, tungsten.

The conductive layer 24 is provided above the topmost conductive layer 23, with an insulating layer interposed therebetween. The conductive layer 24 is formed, for example, in a plate shape extending along the XY plane. The conductive layer 24 is used as a select gate line SGD. The conductive layer 24 contains, for example, tungsten.

A conductive layer 25 is provided above the conductive layer 24, with an insulating layer interposed therebetween. Each conductive layer 25 is formed in, for example, a linear shape extending along the Y direction, and is used as a bit line BL. That is, a plurality of conductive layers 25 are arranged along the X direction in an unillustrated area. The conductive layers 25 contain, for example, copper.

Each of the memory pillars MP is provided so as to extend along the Z direction and penetrates the conductive layers 22 to 24. Each memory pillar MP includes, for example, a core member 30, a semiconductor layer 31, and a stacked film 32. The core member 30 is provided so as to extend along the Z direction. For example, an upper end of the core member 30 is included in a layer above the topmost conductive layer 24, and a lower end of core member 30 is included in a layer in which the conductive layer 21 is provided. The semiconductor layer 31 covers, for example, the periphery of the core member 30. At a bottom portion of the memory pillar MP, a portion of the semiconductor layer 31 is in contact with the conductive layer 21. The stacked film 32 covers a side surface and a bottom surface of the semiconductor layer 31, except for a portion at which the semiconductor layer 31 and the conductive layer 21 are in contact with each other. The core member 30 contains, for example, an insulator such as silicon oxide. The semiconductor layer 31 contains, for example, silicon.

In the above-described structure of the memory pillar MP, a portion at which the memory pillar MP and the conductive layer 22 intersect each other functions as a select transistor ST2. A portion at which the memory pillar MP intersects each conductive layer 23 functions as a memory cell transistor MT. A portion at which the memory pillar MP and the conductive layer 24 intersect each other functions as a select transistor ST1.

A pillar-shaped contact CV is provided on an upper surface of the semiconductor layer 31 in the memory pillar MP. In the illustrated area, two contacts CV respectively corresponding to two of the six memory pillars MP are shown. A contact CV is coupled, in an unillustrated area, to a memory pillar MP to which a contact CV is not coupled and which does not overlap the slit SHE in the illustrated area.

A top surface of the contact CV is in contact with one of the conductive layers 25, namely, one of the bit lines BL. A single contact CV is coupled to one of the conductive layers 25 in each space separated by the slits SLT and SHE. That is, a single memory pillar MP between adjacent slits SLT and SHE and a single memory pillar MP between two adjacent slits SHE are electrically coupled to each of the conductive layers 25.

The slits SLT are formed, for example, in the shape of a plate that extends along the XZ plane, and split the conductive layers 22 to 24. In the slit SLT, the contact LI is provided along the slit SLT, and the spacer SP is provided at least between the contact LI and the conductive layers 22 to 24. An upper end of the contact LI is included in a layer between the conductive layer 24 and the conductive layer 25. A lower end of the contact LI is in contact with, for example, the conductive layer 21. The contact LI in the slit SLT may be omitted, according to the structure of the memory cell array 10.

The slits SHE are formed in a shape of a plate that extends along the XZ plane for example, and split the conductive layer 24. An upper end of the slit SHE is included in a layer between the conductive layer 24 and the conductive layer 25. A lower end of the slit SHE is included in, for example, a layer between the topmost conductive layer 23 and the conductive layer 24. The slit SHE contains, for example, an insulator such as a silicon oxide. An upper end of the slit SHE and an upper end of the slit SLT may be either aligned or not aligned. An upper end of the slit SHE and an upper end of the memory pillar MP may be either aligned or not aligned.

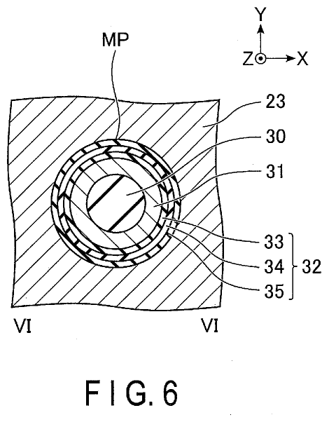

FIG. 6 is a cross-sectional view taken along line VI-VI of FIG. 5, showing an example of a cross-sectional structure of a memory pillar MP in the semiconductor memory device 1 according to the embodiment. More specifically, FIG. 6 illustrates a cross-sectional structure of a memory pillar MP in a layer that is parallel to the surface of the semiconductor substrate 20 and that includes the conductive layer 23.

As shown in FIG. 6, the stacked film 32 includes, for example, a tunnel insulating film 33, an insulating film 34, and a block insulating film 35. In a layer including the conductor layer 23, the core member 30 is provided, for example, in the middle of the memory pillar MP. The semiconductor layer 31 surrounds a side surface of the core member 30. The tunnel insulating film 33 surrounds a side surface of the semiconductor layer 31. The insulating film 34 surrounds a side surface of the tunnel insulating film 33. The block insulating film 35 surrounds a side surface of the insulating film 34. The conductor layer 23 surrounds a side surface of the block insulating film 35.

The semiconductor layer 31 is used as a channel (current path) of each of the memory cell transistors MT0 to MT7 and the select transistors ST1 and ST2. Both of the tunnel insulating film 33 and the block insulating film 35 contain, for example, a silicon oxide. The insulating film 34 is used as a charge storage layer of the memory cell transistor MT, and contains, for example, silicon nitride. Thereby, each memory pillar MP functions as a single NAND string NS.

(Structure of Memory Cell Array 10 in Hookup Area HA)

In the semiconductor memory device 1 according to the embodiment, the structure of an even-numbered block BLK in the hookup area HA1 is similar to the structure of an odd-numbered block BLK in the hookup area HA2. Also, the structure of an even-numbered block BLK in the hookup area HA2 is similar to the structure of an odd-numbered block BLK in the hookup area HA1.

Specifically, the planar layout of the block BLK0 in the hookup area HA2 is, for example, the same as the layout in which the structure of the block BLK1 in the hookup area HA1 is inverted with respect to the X and Y directions. The planar layout of the block BLK1 in the hookup area HA2 is, for example, the same as the layout in which the structure of the block BLK0 in the hookup area HA1 is inverted with respect to the X and Y directions. Hereinafter, an even-numbered block BLK will be referred to as “BLKe”, and an odd-numbered block BLK will be referred to as “BLKo”.

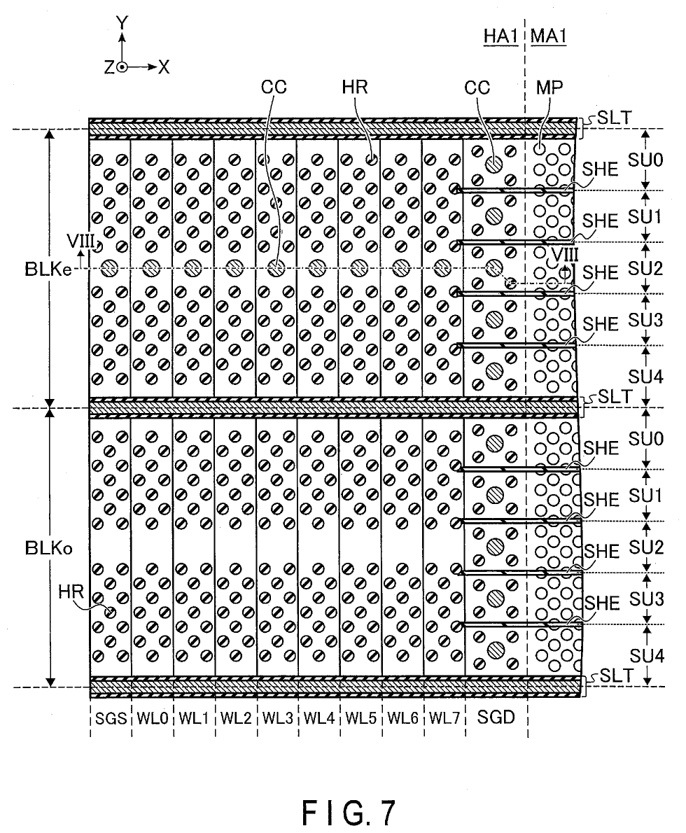

FIG. 7 shows an example of a detailed planar layout of the hookup area HA1 of the memory cell array 10 included in the semiconductor memory device 1 according to the embodiment, illustrating an area corresponding to adjacent blocks BLKe and BLKo. In FIG. 7, a portion of the memory area MA1 in the vicinity of the hookup area HA1 is also shown. Hereinafter, a planar layout of a block BLK in the hookup areas HA1 and HA2 will be described based on the planar layout of the blocks BLKe and BLKo in the hookup area HA1 shown in FIG. 7.

As shown in FIG. 7, in the hookup area HA1, each of a select gate line SGS, word lines WL0 to WL7, and a select gate line SGD includes a portion (terrace portion) that does not overlap its upper interconnect layer (conductive layer). In the hookup area HA1, the memory cell array 10 includes a plurality of contacts CC and a plurality of support pillars HR.

In the hookup area HA1, the portion that does not overlap the upper interconnect layer is in a shape similar to the shape of a staircase, a terrace, rimstone, etc. Specifically, steps are individually provided between the select gate line SGS and the word line WL0, between the word line WL0 and the word line WL1, between the word line WL6 and the word line WL7, and between the word line WL7 and the select gate line SGD. In the present example, end portions of the word lines WL0 to WL7 are provided in a staircase shape in which steps are formed in the X direction.

In an area in which the hookup area HA1 and the block BLKe overlap each other, a plurality of contacts CC are respectively provided on terrace portions of the select gate line SGS, the word lines WL0 to WL7, and the select gate lines SGD0 to SGD4. In an area in which the hookup area HA1 and the block BLKo overlap each other, a plurality of contacts CC are respectively provided in terrace portions of the select gate lines SGD0 to SGD4.

In an area in which the hookup area HA2 and the block BLKo overlap each other, a plurality of contacts CC are respectively provided on terrace portions of the select gate line SGS, the word lines WL0 to WL7, and the select gate lines SGD0 to SGD4, even though such a configuration is not illustrated. In an area in which the hookup area HA2 and the block BLKe overlap each other, a plurality of contacts CC are respectively provided on terrace portions of the select gate lines SGD0 to SGD4.

The select gate line SGS, the word lines WL0 to WL7, and the select gate lines SGD0 to SGD4 are electrically coupled to the row decoder module 15 via the corresponding contacts CC. That is, voltages are applied to the select gate line SGS, the word lines WL0 to WL7, and the select gate lines SGD0 to SGD4 via, for example, the contact CC arranged in at least one of the hookup areas HA1 and HA2. In the interconnect layer, the contact CC may be coupled to each of the hookup area HA1 and the hookup area HA2. In this case, voltages are applied to the word line WL from, for example, both the contacts CC in the hookup area HA1 and the contacts CC in the hookup area HA2.

A plurality of support pillars HR are suitably arranged in an area in which each of the hookup areas HA1 and HA2 and the blocks BLK overlap each other, except for portions at which the slits SLT are formed and portions at which the contacts CC are formed. It is preferable that the support pillars HR not overlap the contacts CC and the slits SLT. Each support pillar HR has a structure in which an insulator is embedded in a hole extending in the Z direction, and penetrates a stack of interconnect layers (e.g., the word lines WL and the select gate lines SGS and SGD).

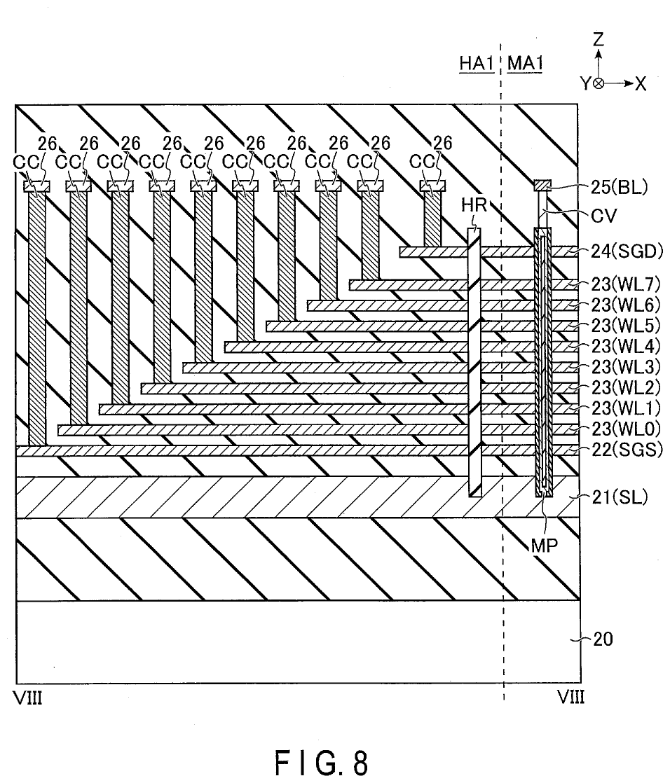

FIG. 8 is a cross-sectional view taken along line VIII-VIII in FIG. 7, showing an example of a cross-sectional structure of the hookup area HA1 of the memory cell array 10 included in the semiconductor memory device 1 according to the embodiment. In FIG. 8, a portion of the memory area MA1 in the vicinity of the hookup area HA1 is also shown. As shown in FIG. 8, in the hookup area HA1, end portions of the conductive layers 22, 23, and 24 corresponding to the word lines WL and the select gate lines SGD and SGS are provided in a staircase shape. In the hookup area HA1, the memory cell array 10 includes a plurality of conductive layers 26.

The contacts CC are provided on the respective terrace portions of the select gate line SGS, the word lines WL0 to WL7, and the select gate lines SGD. A single conductive layer 26 is provided on each contact CC. Thereby, the conductive layers 22, 23, and 24 and the conductive layer 26 associated therewith are electrically coupled via the contact CC. The conductive layer 26 is included in, for example, the same layer as the conductive layer 25.

The support pillars HR are provided so as to extend in the Z direction, and penetrate, for example, the conductive layers 22 to 24. An upper end of the support pillar HR is included in, for example, a layer between the conductive layer 25 and an upper end of the memory pillar MP. A lower end of the support pillar HR is included in, for example, a layer in which the conductive layer 21 is provided.

When a semiconductor layer that is used as part of the select gate line SGS and an etching stopper is provided between the conductive layer 21 and the conductive layer 22, it suffices that a lower end of the support pillar HR reaches at least the semiconductor layer. The support pillars HR may be configured of multiple types of insulating layers. In the support pillars HR, a conductor or a semiconductor that is insulated from the conductive layers 22 to 24 may be contained.

(Structure of Memory Cell Array 10 in Contact Area CA)

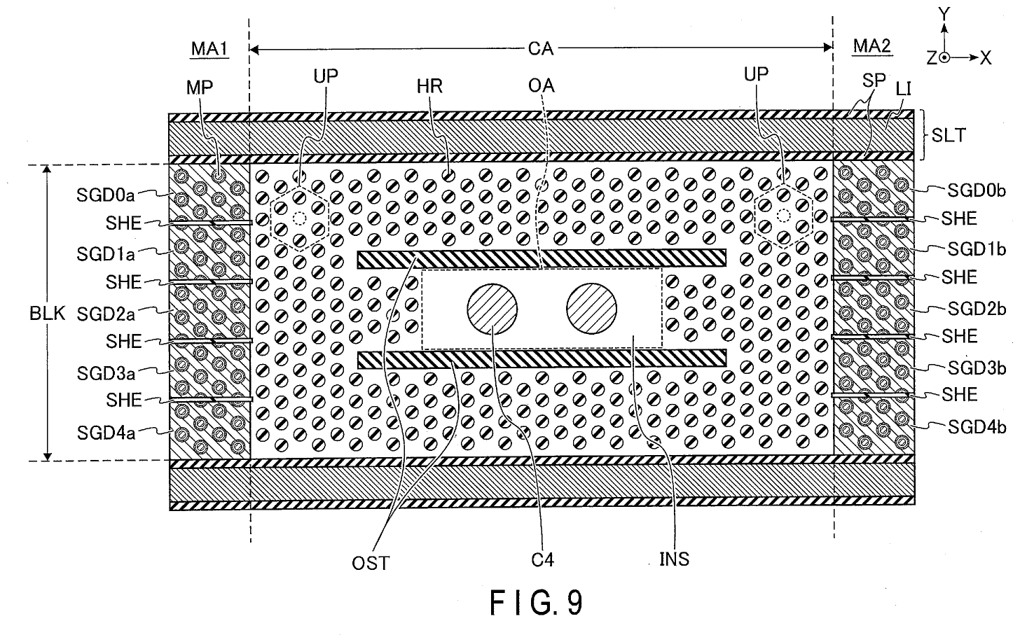

FIG. 9 shows an example of a detailed planar layout of a contact area CA of the memory cell array 10 included in the semiconductor memory device 1 according to the embodiment. In FIG. 9, part of the memory areas MA1 and MA2 in the vicinity of the contact area CA is also shown. As shown in FIG. 9, select gate lines SGD provided in the memory area MA1 and select gate lines SGD provided in the memory area MA2 are split via, for example, an insulating layer INS in the contact area CA. In the contact area CA, the memory cell array 10 includes contacts C4 and a plurality of support pillars HR.

The select gate line SGD0 corresponding to the string unit SU0 is partitioned into a select gate line SGD0a in the memory area MA1 and a select gate line SGD0b in the memory area MA2. The select gate line SGD1 corresponding to the string unit SU1 is partitioned into a select gate line SGD1a in the memory area MA1 and a select gate line SGD1b in the memory area MA2. Similarly, a set of select gate lines SGD2a and SGD2b, a set of select gate lines SGD3a and SGD3b, and a set of select gate lines SGD4a and SGD4b, respectively corresponding to the string units SU2 to SU4, are formed.

Each of the select gate lines SGD0a to SGD4a includes a portion that extends in the X direction in the memory area MA1. Each of the select gate lines SGD0b to SGD4b includes a portion that extends in the X direction in the memory area MA2. The set of select gate lines SGD provided for each string unit SU may be electrically coupled to each other via an unillustrated interconnect, or may be continuously formed if a pattern that circumvents an insulating layer INS can be formed.

The contacts C4 are provided in a penetration area OA. Specifically, the contacts C4 are provided between two slits OST arranged between adjacent slits SLT. Each contact C4 penetrates a stacked structure of the memory cell array 10. The contact C4 electrically couples an interconnect above the memory cell array 10 and an interconnect below the memory cell array 10. In the penetration area OA, one or more contacts C4 may be provided.

The support pillars HR are periodically arranged in an area in the contact area CA from which the penetration area OA is excluded. The support pillars HR in the contact area CA may be arranged either in a staggered manner or in a lattice pattern. It is preferable that the support pillars HR not overlap the slits SLT and OST. The structure of the support pillars HR in the contact area CA is, for example, similar to the structure of the support pillars HR in the hook area HA.

In the contact area CA, a single support pillar HR is eliminated, for example, from a plurality of support pillars HR that are periodically arranged, in the vicinity of the boundary between the memory area MA1 and the contact area CA. Specifically, in the contact area CA, for example, a plurality of support pillars HR include six support pillars HR that are arranged at vertex portions of a hexagonal shape, and a support pillar HR in an area surrounded by the six support pillars HR is omitted.

Hereinafter, a portion of an area in which a plurality of support pillars HR are periodically arranged and from which a support pillar HR is eliminated will be referred to as a “unique pattern UP”. At least one unique pattern UP is arranged, for example, between adjacent slits SLT. The unique pattern UP may be provided in each of the vicinity of a boundary between the memory area MA1 and the contact area CA, and the vicinity of a boundary between the memory area MA2 and the contact area CA.

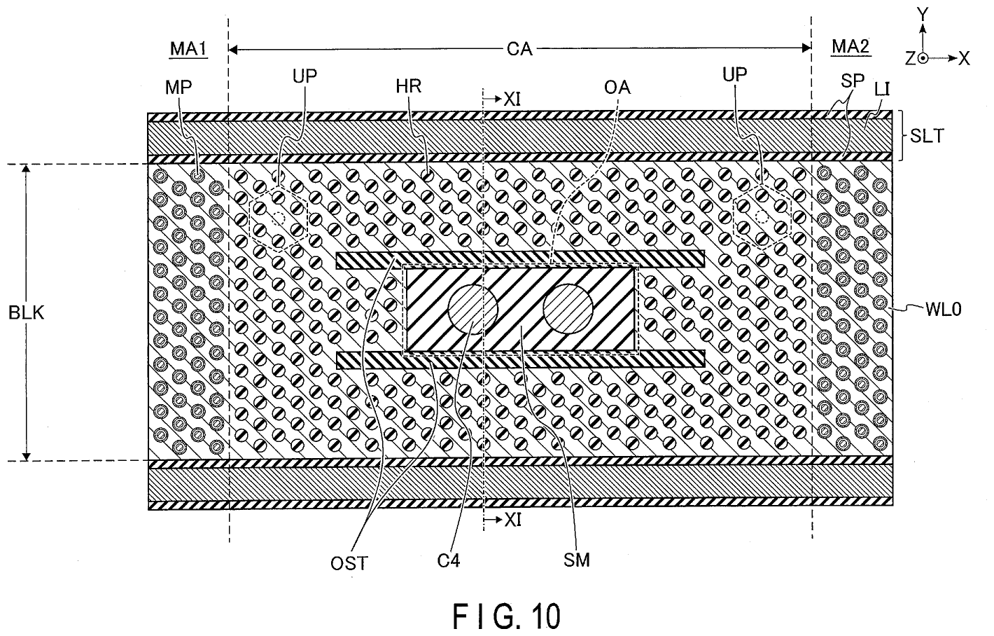

FIG. 10 is an example of a cross-sectional structure in the contact area CA of the memory cell array 10 included in the semiconductor memory device 1 according to the embodiment, showing a cross section that includes the conductive layer 23 corresponding to the word line WL0 and that is parallel to a surface of the semiconductor substrate 20. In FIG. 10, part of the memory areas MA1 and MA2 in the vicinity of the contact area CA is also shown. As shown in FIG. 10, the word line WL0 (conductive layer 23) is continuously provided between the memory areas MA1 and MA2 via the contact area CA. In the contact area CA, the memory cell array 10 further includes a sacrificial member SM.

The sacrificial member SM is a member that is used for a replacement process of the stacked interconnects. In the replacement process, the sacrificial member SM corresponds to a portion of an insulator that remains without having been replaced by a conductor, and is arranged in a same layer as the conductive layer 23 after the replacement process. The sacrificial member SM is provided in the penetration area OA, and is in contact with each of the slits OST adjacent to one another in the Y direction. In other words, the slit OST extends in the X direction between the conductive layer 23 and the sacrificial member SM which is an insulating layer. In the penetration area OA, the sacrificial member SM separates, in the X direction, the conductive layer 23 which is in contact with the side of the memory area MA1, and the conductive layer 23 which is in contact with the side of the memory area MA2. The portion of the conductive layer 23 which is in contact with the sacrificial member SM is located between the slits OST that are adjacent to each other in the Y direction. The contact C4 penetrates the sacrificial member SM. The sacrificial member SM contains, for example, silicon nitride.

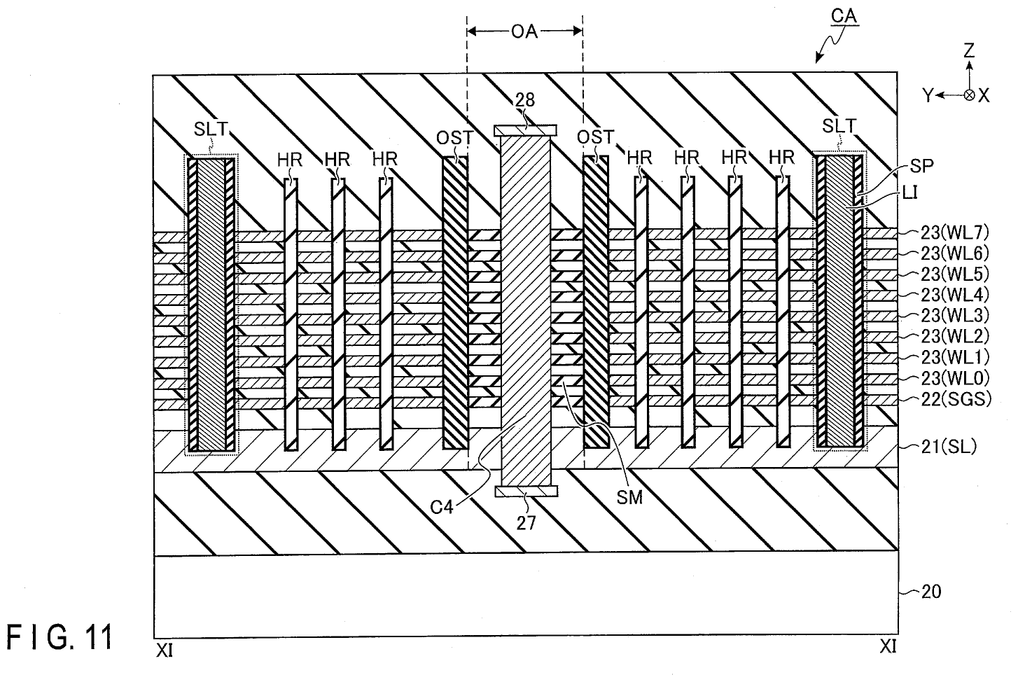

FIG. 11 is a cross-sectional view taken along line XI-XI in FIG. 10, showing an example of a cross-sectional structure of the contact area CA of the memory cell array 10 included in the semiconductor memory device 1 according to the embodiment. As shown in FIG. 11, the memory cell array 10 further includes conductive layers 27 and 28 in the contact area CA.

Each slit OST includes a portion that extends in the Z direction. An upper end of the slit OST is included in a layer between an unillustrated conductive layer 24 and an unillustrated conductive layer 25. A lower end of the slit OST is included in, for example, a layer in which the conductor layer 21 is provided. In a portion that is at the same layer as the conductive layer 22 and that is interposed by two slits OST, a sacrificial member SM is provided. Similarly, in a portion that is at the same layer as the conductive layer 23 and that is interposed by two slits OST, a sacrificial member SM is provided. In the contact area CA, an insulator, for example, is provided at the same layer as the conductive layer 24.

The conductive layer 27 is provided at a layer between the semiconductor substrate 20 and the conductive layer 21, and is coupled to a circuit below the memory cell array 10. A contact C4 is provided on the conductive layer 27. The contact C4 is provided so as to extend in the Z direction, and penetrates the insulating layer and the sacrificial members SM in the contact area CA. An insulating layer (not illustrated) is arranged between the contact C4 and the conductive layer 21, and the contact C4 and the conductive layer 21 are distanced and insulated from each other. A conductive layer 28 is provided above the contact C4. The conductive layer 28 is provided at the same layer as the conductive layer 26, and is coupled to a circuit above the memory cell array 10. Coupling between the contact C4 and the conductive layer 28 may be provided via another contact.

In the above description, a case has been explained where the memory cell array 10 includes a single contact area CA; however, the memory cell array 10 may include a plurality of contact areas CA. In this case, the memory area MA between the hookup areas HA1 and HA2 is divided into three or more sections. The contact area CA may be provided in the hookup area HA. When the contact area CA is formed in the hookup area HA, the above-described structure relating to the select gate line SGD may be suitably omitted.

### [2] Method of Manufacturing Semiconductor Memory Device 1

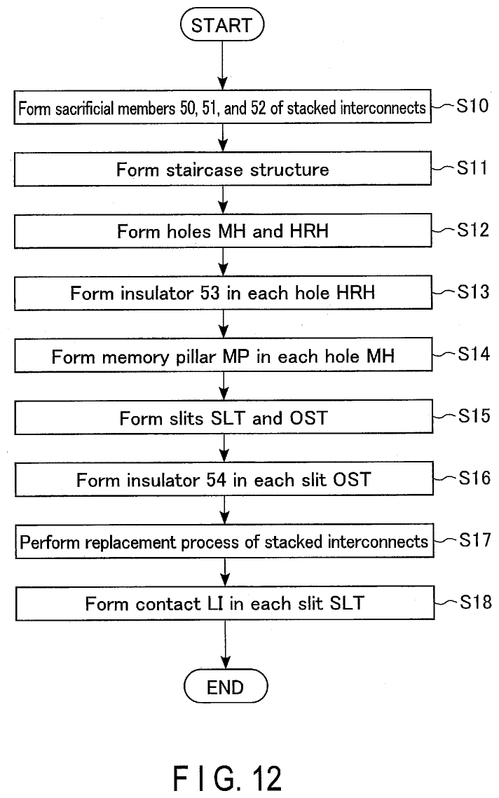

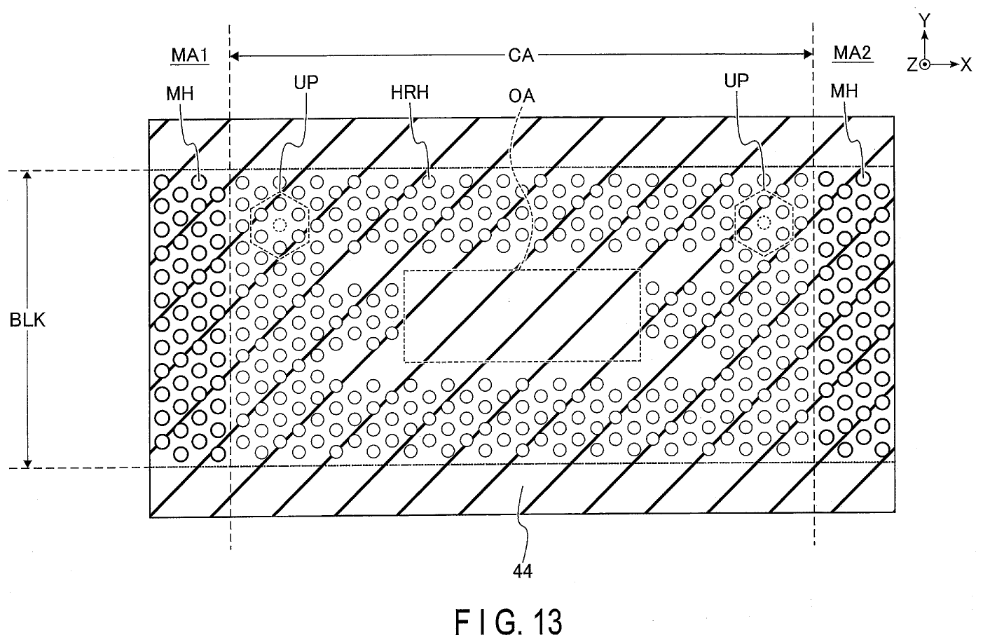

FIG. 12 shows an example of a flowchart of a method of manufacturing a semiconductor memory device 1 according to the embodiment. Each of FIGS. 13 to 26 shows an example of a planar layout or a cross-sectional structure in the course of manufacturing of the semiconductor memory device 1 according to the embodiment. The illustrated planar layout shows an area corresponding to FIG. 9. The illustrated cross-sectional structure shows both the area corresponding to FIG. 11 and part of the memory area MA. As shown in FIG. 12, in the manufacturing process of the semiconductor memory device 1 according to the embodiment, steps S10 to S18 are sequentially performed. Hereinafter, an example of a manufacturing process relating to a stacked interconnect structure in the memory cell array 10 of the semiconductor memory device 1 according to the embodiment will be described, with reference to FIG. 12.

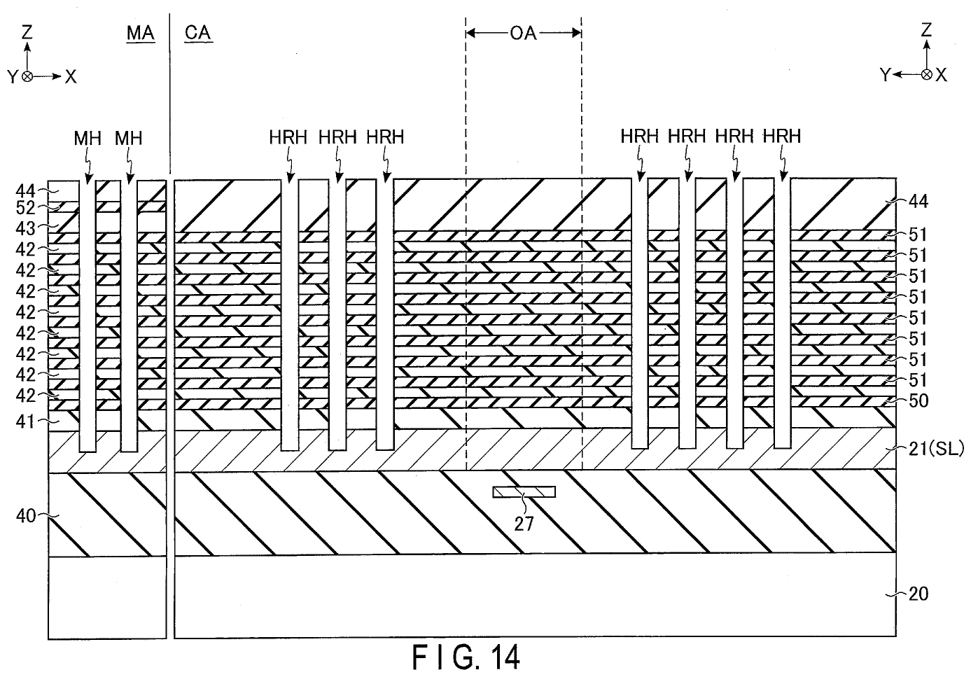

First, the processes at steps S10 to S12 are sequentially performed, sacrificial members 50, 51, and 52 of stacked interconnects are formed, as shown in FIGS. 13 and 14, a staircase structure of the stacked interconnects is formed, and a plurality of holes MH and HRH are formed.

Briefly speaking, an insulating layer 40 including a conductive layer 27 and circuitry (not illustrated) corresponding to, for example, the sense amplifier module 16 is formed on a semiconductor substrate 20. A conductive layer 21, an insulating layer 41, and a sacrificial member 50 are sequentially formed on the insulating layer 40. Insulating layers 42 and sacrificial members 51 are stacked in an alternating manner on the sacrificial member 50. An insulating layer 43 and a sacrificial member 52 are sequentially formed on the topmost sacrificial member 51 (step S10).

End portions of the stacked sacrificial members 50 to 52 are processed into a staircase shape in the hookup areas HA1 and HA2, and the sacrificial member 52 in the contact area CA, for example, is removed. Thereafter, the staircase portions in the hookup areas HA1 and HA2 and the step portion in the contact area CA are embedded by the insulating layer 44, and the top surface of the insulating layer 44 is planarized by, for example, chemical mechanical polishing (CMP) (step S11).

Thereafter, a mask including openings at positions corresponding to memory pillars MP and support pillars HR is formed by, for example, photolithography. By anisotropic etching using the mask, holes MH and HRH that penetrate, for example, the insulating layers 41 to 44 and the sacrificial members 50 to 52 are formed, and a portion of the conductive layer 21 is exposed at the bottom portions of the holes (step S12). The holes MH and HRH respectively correspond to the memory pillars MP and the support pillars HR.

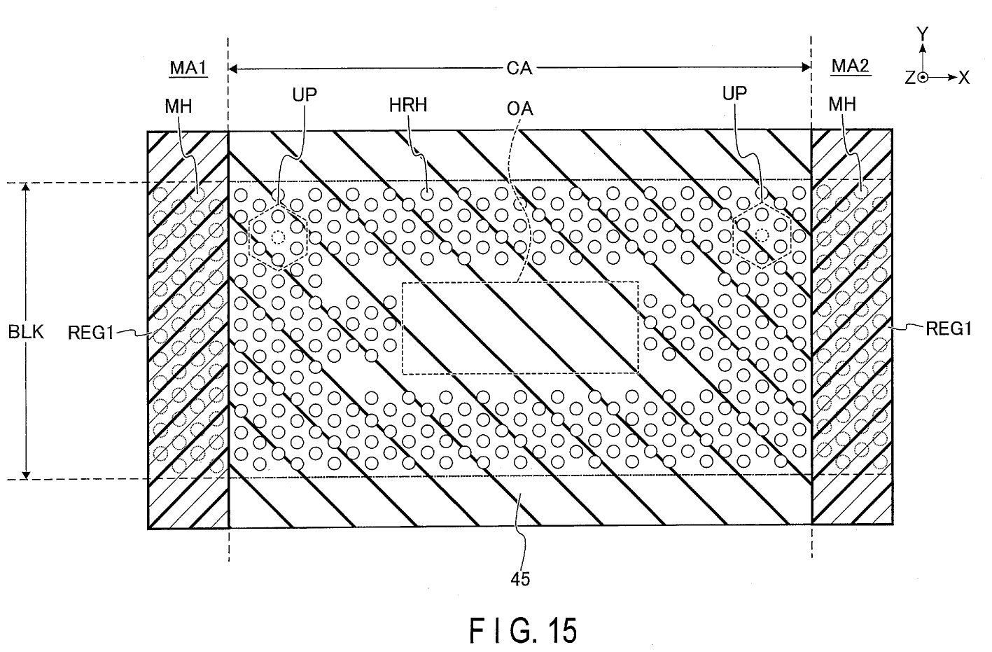

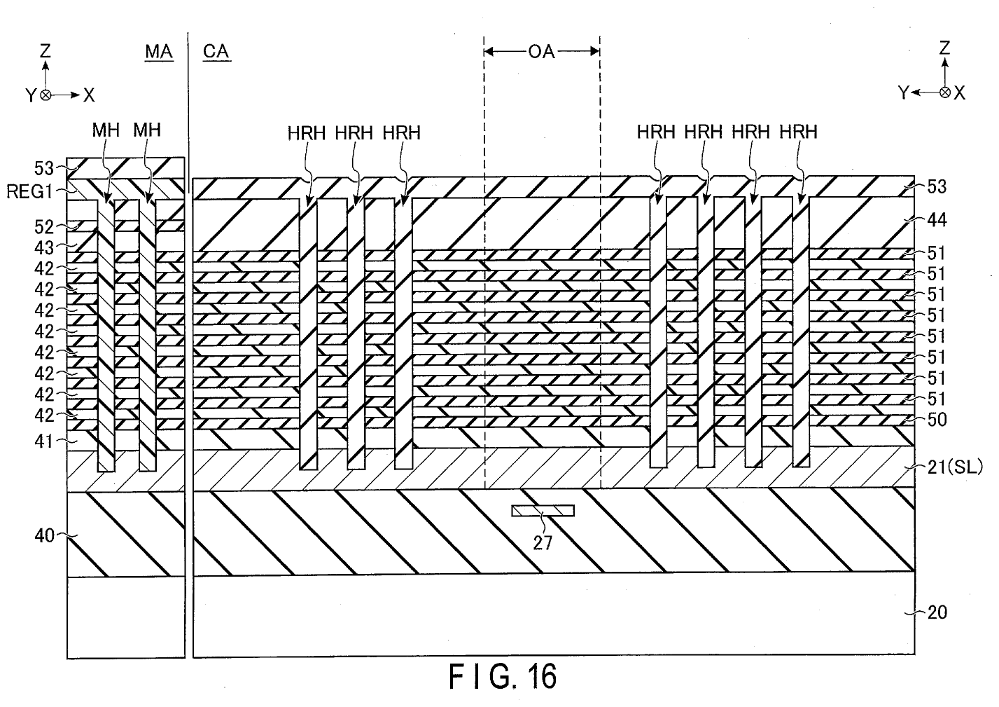

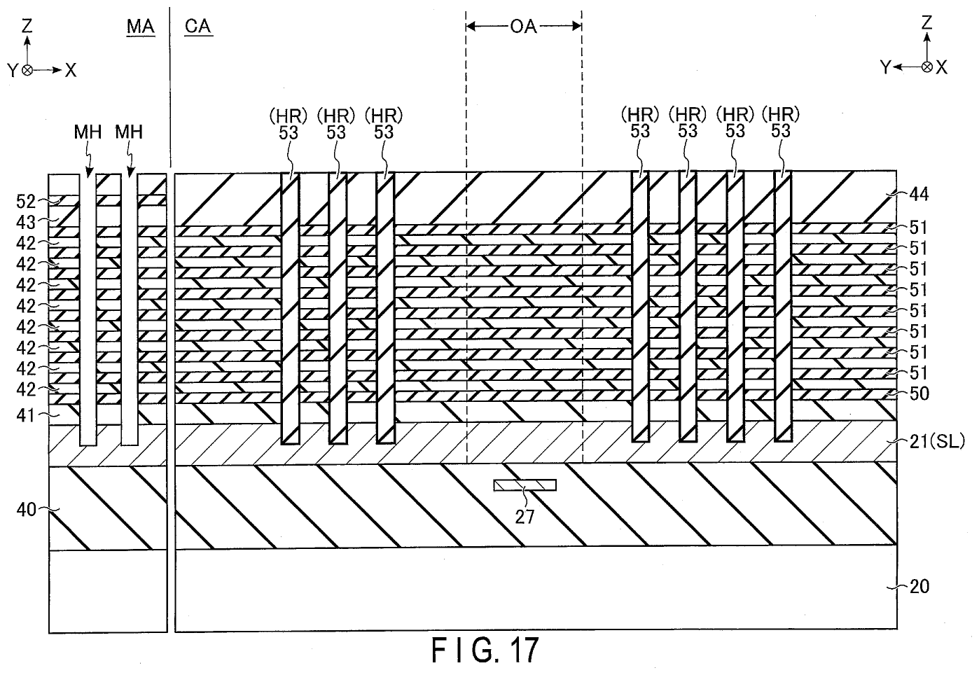

Subsequently, an insulator 53 is formed in each hole HRH by the process at step S13. Specifically, as shown in FIG. 15, a mask REG1 which includes an opening in a portion in which a plurality of holes HRH are provided and which covers a portion in which a plurality of holes MH are provided is formed. The mask REG1 at least covers the entire area in which the memory area MA and each block BLK overlap. The mask REG1 is formed by, for example, photolithography. The mask REG1 is not limited thereto, and may be a hard mask processed by photolithography and etching. The insulator 53 is formed so as to fill in each hole HRH, as shown in FIG. 16. Thereafter, the insulator 53 formed outside the hole HRH and the mask REG1 are removed, as shown in FIG. 17. Thereby, the insulator 53 remains in each hole HRH, and structures corresponding to the support pillars HR are formed.

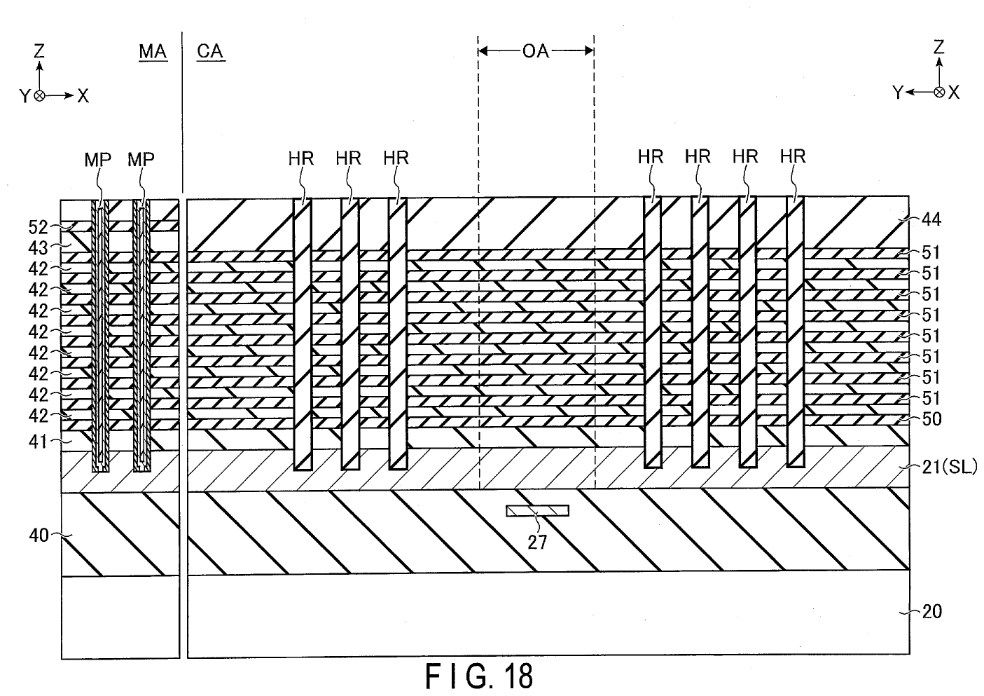

Subsequently, as shown in FIG. 18, a memory pillar MP is formed in each hole MH by the process at step S14. Briefly speaking, a block insulating film 35, an insulating film 34, and a tunnel insulating film 33 are sequentially formed on a side surface and a bottom surface of each hole MH. Part of the block insulating film 35, the insulating film 34, and the tunnel insulating film 33 provided at a bottom portion of the hole MH is removed, and the semiconductor layer 31 and the core member 30 are formed in the hole MH. Thereafter, a portion of the core member 30 provided at an upper part of the hole MH is removed, and the semiconductor layer 31 is formed in that portion. Thereby, a structure corresponding to a memory pillar MP is formed in each hole MH.

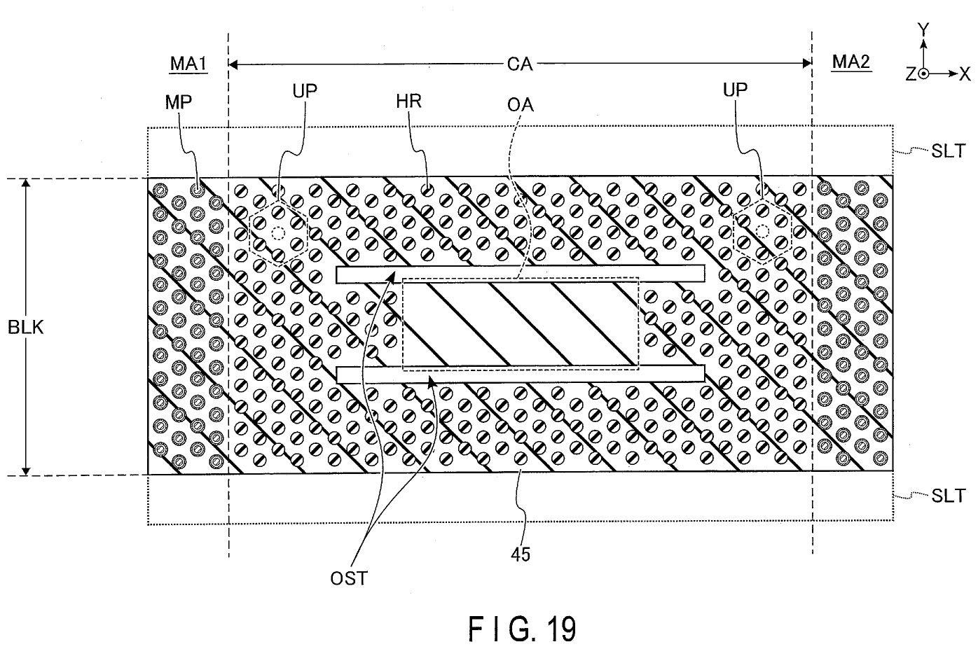

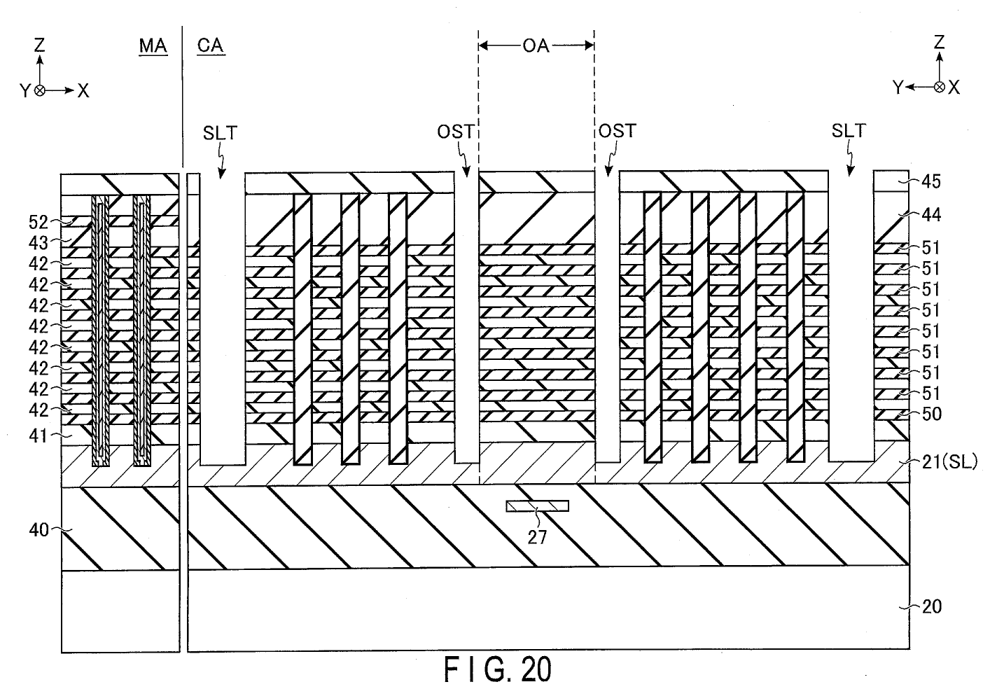

Subsequently, as shown in FIGS. 19 and 20, a plurality of slits SLT and OST are collectively formed by the processing at step S15. Specifically, an insulating layer 45, for example, is formed on an insulating layer 44. Thereafter, a mask with openings at positions corresponding to the slits SLT and OST is formed by, for example, photolithography. Slits SLT that penetrate, for example, the insulating layers 41 to 45 and the sacrificial members 50 to 52 and slits OST that penetrate the insulating layers 41, 42, 44 and 45, and the sacrificial members 50 and 51 are formed by anisotropic etching using the mask.

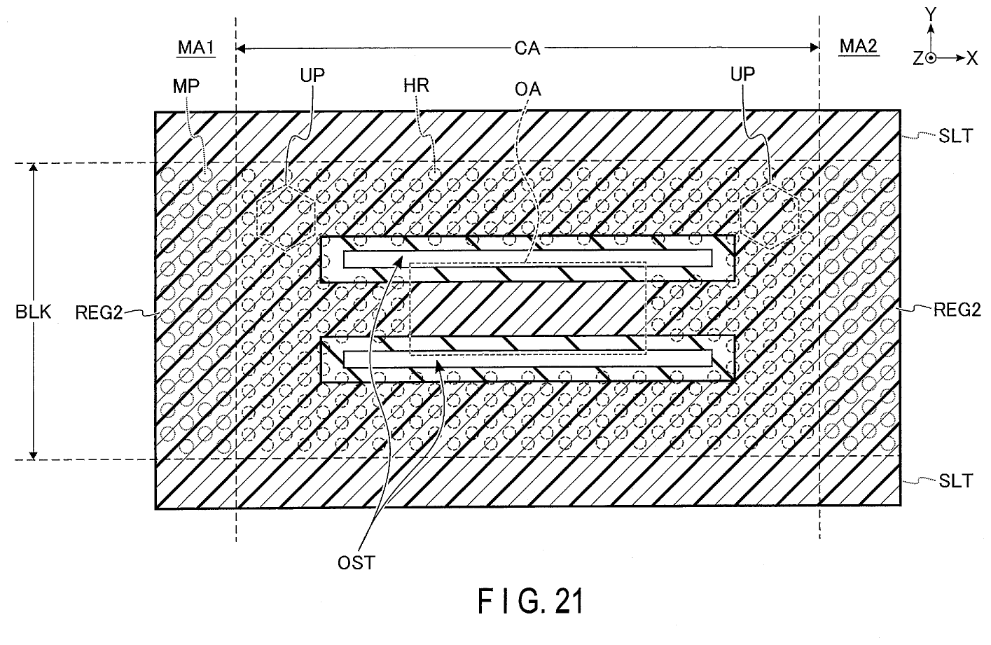

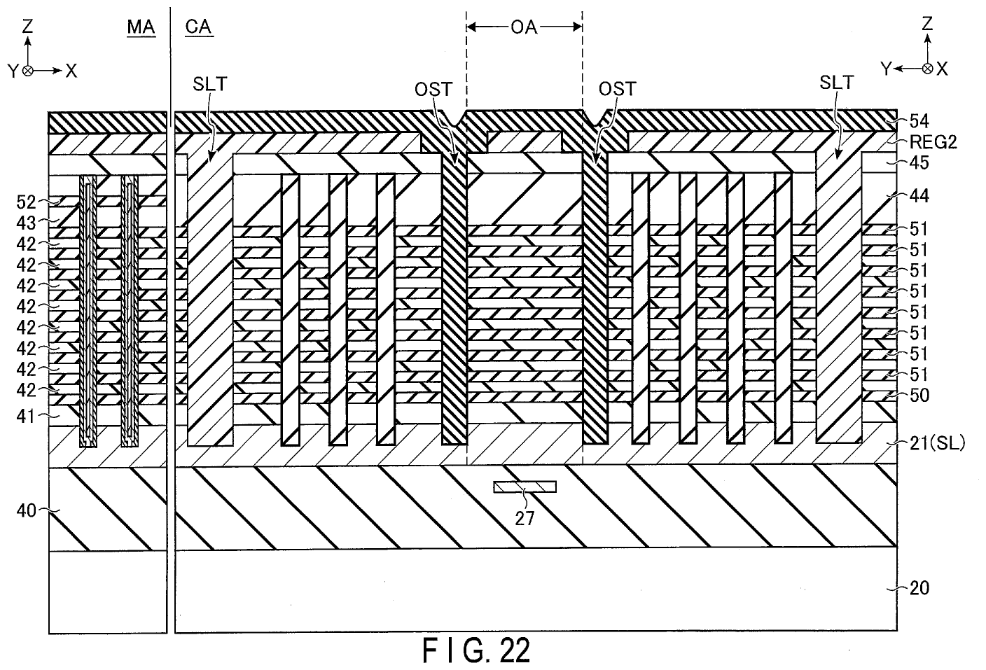

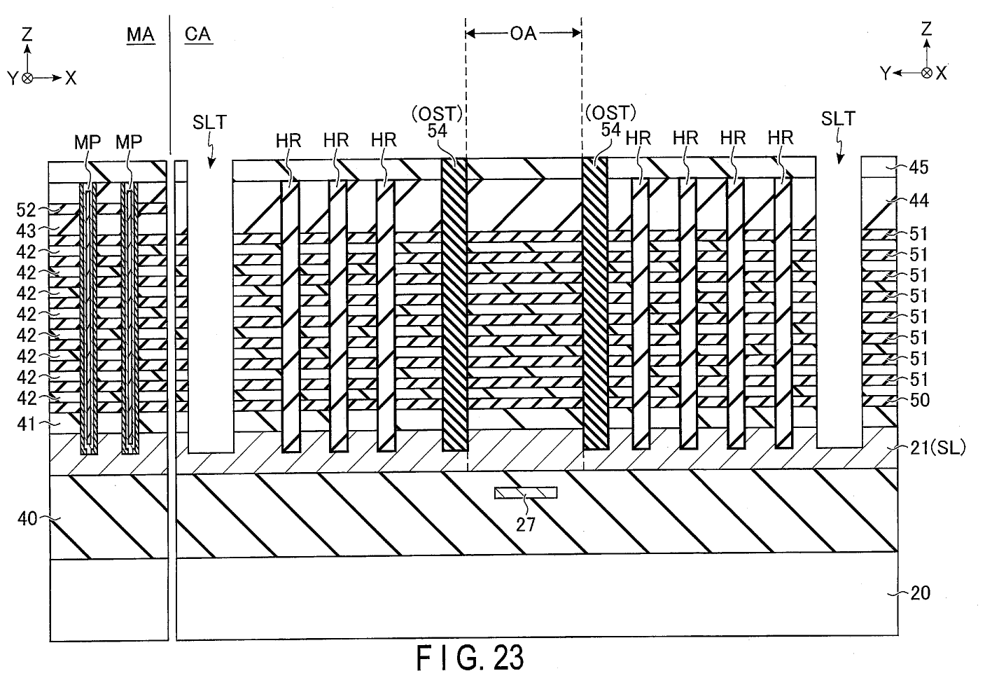

Subsequently, an insulator 54 is formed in each slit OST by the process at step S16. Specifically, as shown in FIG. 21, a mask REG2 which includes a plurality of openings in portions in which the slits OST are respectively provided and which covers the slits SLT is formed. The mask REG2 is formed by, for example, photolithography. The mask REG2 is not limited thereto, and may be a hard mask processed by photolithography and etching. The insulator 54 is formed so as to fill in each slit OST, as shown in FIG. 22. Thereafter, the insulator 54 formed outside the slit OST and the mask REG2 are removed, as shown in FIG. 23. Thereby, a structure in which the insulator 54 remains in each slit OST is formed.

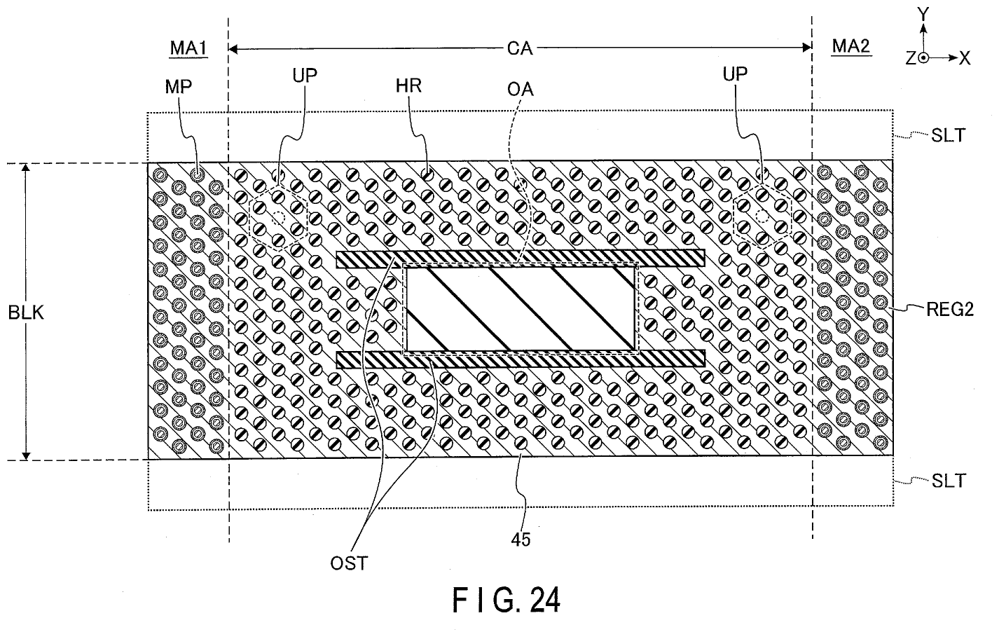

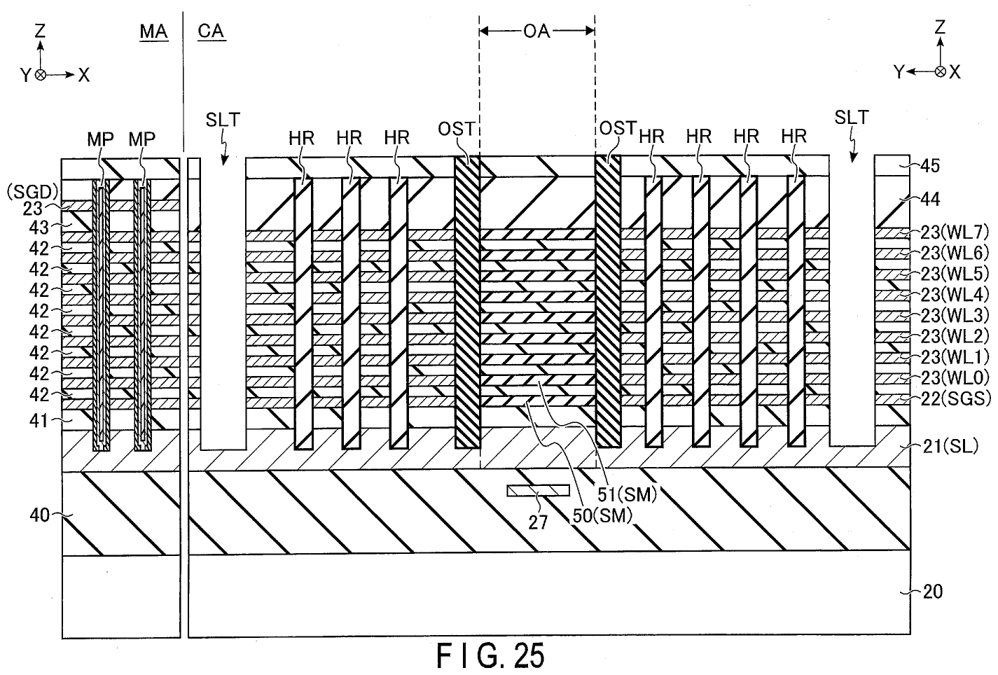

Subsequently, as shown in FIGS. 24 and 25, a replacement process of the stacked interconnects is performed by the process at step S17, and a stacked interconnect structure is formed. Specifically, sacrificial members 50 to 52 are selectively removed via the slit SLT by wet etching using, for example, thermal phosphoric acid. The wet etching is set in such a manner that the sacrificial members 50 and 51 in the penetration area OA remain. The three-dimensional architecture of the structure from which the sacrificial members 50 to 52 have been removed is maintained by the memory pillars MP, the support pillars HR, and the slits OST. Thereafter, a conductor is embedded in the space from which the sacrificial members 50 to 52 have been removed, via the slit SLT. For the formation of the conductor in this step, chemical vapor deposition (CVD), for example, is used.

Thereafter, the conductor formed inside the slit SLT is removed by an etchback process, and the conductor formed in adjacent interconnect layers is separated. Thereby, a conductive layer 22 which functions as a select gate line SGS, conductive layers 23 which respectively function as word lines WL0 to WL7, and a plurality of conductive layers 24 which function as a select gate line SGD, are formed. The conductive layers 22 to 24 formed in this step may include a barrier metal. In the formation of the conductor after the removal of the sacrificial members 50 to 52, tungsten is formed after, for example, a titanium nitride film is formed as a barrier metal.

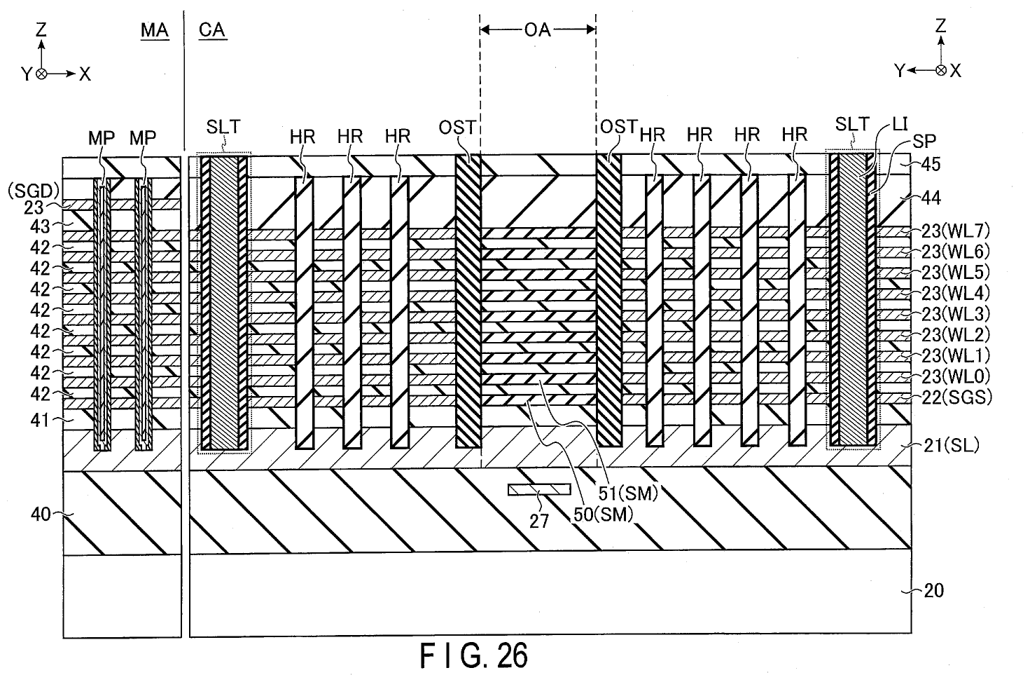

Lastly, a contact LI is formed in each slit SLT, as shown in FIG. 26, by the process at step S18. Specifically, an insulating film (spacer SP) is formed so as to cover a side surface and a bottom surface of each slit SLT. Thereafter, a portion of the spacer SP provided at a bottom portion of the slit SLT is removed, and a portion of the conductive layer 21 is exposed at the bottom portion of the slit SLT. After that, a conductor (contact LI) is formed in the slit SLT, and the conductor formed outside the slit SLT is removed by, for example, CMP.

By the manufacturing process of the semiconductor memory device 1 according to the embodiment described above, the stacked interconnect structure in the memory cell array 10 is formed. The above-described manufacturing process is merely an example, and the manufacturing process is not limited thereto. For example, other processes may be inserted between the manufacturing steps, and some of the steps may be omitted or integrated. The manufacturing steps may be interchanged where possible. For example, the step of forming memory pillars MP and the step of forming an insulator 53 in holes HRH may be interchanged.

### [3] Advantageous Effects of Embodiment

The semiconductor memory device 1 according to the above-described embodiment is capable of improving the yield of the semiconductor memory device 1. Hereinafter, details of the advantageous effects of the semiconductor memory device 1 according to the embodiment will be described.

In a semiconductor memory device comprising three-dimensionally stacked memory cells, stacked interconnects such as word lines WL are formed by, for example, a replacement process of the stacked interconnects. Briefly speaking, insulating layers and sacrificial members are formed in an alternating manner in the replacement process of the stacked interconnects. By selectively removing the sacrificial members and forming a conductor in the space from which the sacrificial members are removed, stacked interconnects such as the word lines WL are formed. To perform such a replacement process, support pillars HR are provided in the memory cell array so as to maintain the three-dimensional structure when the sacrificial members are removed.

To improve the storage density of the semiconductor memory device, increase, for example, in the number of stacks of the word lines WL is taken into consideration. The increase in the number of stacks of the word lines WL causes deep-hole processing of the holes MH for forming the memory pillars MP. The holes HRH for forming the support pillars HR are processed at a depth similar to that of the holes MH, to penetrate the stacked structure of the insulating layers and the sacrificial members. The deep-hole processing of such holes MH and HRH takes a high manufacturing cost and is difficult. Accordingly, it is preferable that the processing of the holes MH and the processing of the holes HRH be collectively performed.

When the holes MH and the holes HRH are collectively processed, and the structure formed in the hole MH and the structure formed in the hole HRH are different, a mask is formed that covers one of the area in which the hole MH is provided (e.g., the memory area MA) and an area in which the hole HRH is provided (e.g., the contact area CA), and different structures are formed to fill in the holes MH and HRH. Since process variations may occur in the formation of the mask, it is preferable that the position of the boundary portion of the area be managed at the time of mass production.

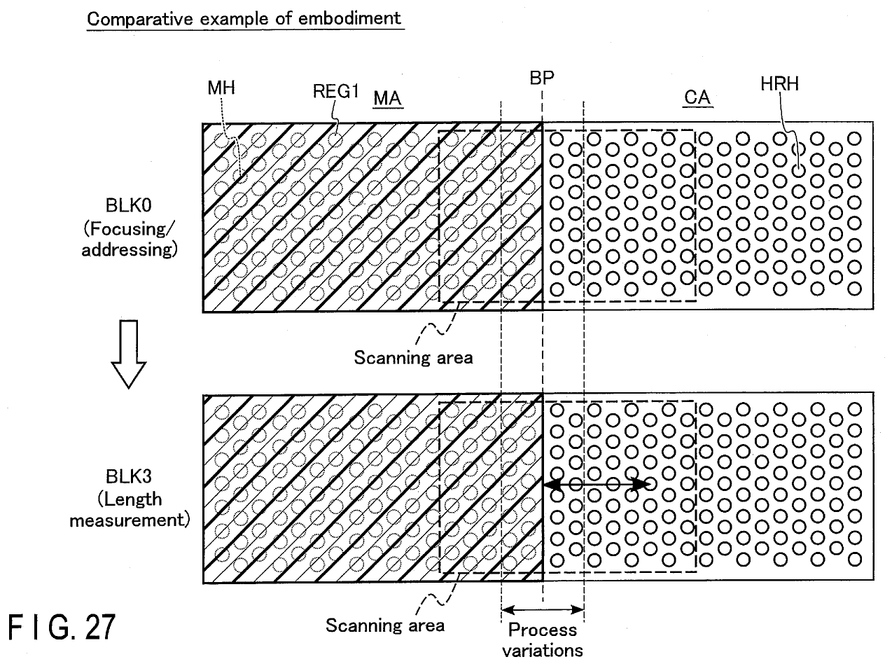

FIG. 27 is a schematic diagram showing an example of a length measurement method in a manufacturing process of the semiconductor memory device according to a comparative example of the embodiment, illustrating an area including a boundary portion BP between the memory area MA and the contact area CA when a mask REG1 is formed in the process at step S13. As shown in FIG. 27, the semiconductor memory device according to the comparative example of the embodiment has a configuration from which the unique pattern UP of the embodiment is omitted.

Examples of the dimension length measurement device include CD-SEM. Such a length measurement device recognizes, for example, an anchor pattern on a wafer to be measured, and performs a focusing process, an addressing process, and a length measurement process with reference to the anchor pattern. The focusing process is performed using an area in the vicinity of an area including a length measurement portion. In the addressing process, which is a process of searching for, for example, a reference for jumping to the length measurement portion, an image comparison is performed between a pattern in a scanning area and a reference pattern acquired in advance. The length measurement device performs a scanning area jump to the length measurement portion with reference to the anchor pattern in the scanning area when, for example, a matching coefficient of an image has exceeded a predetermined threshold value as a result of the image comparison in, for example, the addressing process. When a resist is used as mask REG1, the resist may shrink through the focusing process, and it is preferable that the focus portion and the length measurement portion be set in different areas.

Accordingly, the length measurement device performs a focusing process and an addressing process using, for example, an area including a boundary portion BP of the block BLK0. The length measurement device scans an area including a boundary portion BP of the block BLK3 with reference to the anchor pattern in the block BLK0. The measurement device measures a distance between the boundary portion BP of the block BLK3 and a particular hole HRH set in advance.

However, the position of the boundary portion BP may vary according to the above-described process variations. When the position of the boundary portion BP varies, it becomes difficult for the measurement device to correctly recognize the anchor pattern in the addressing process. When the measurement device has incorrectly recognized the anchor pattern, deviations may occur in the length measurement portion, possibly resulting in erroneous length measurement. The occurrence of such erroneous measurement could be a cause for the support pillars HR not being formed in a desired structure in the subsequent manufacturing step, possibly leading to occurrence of failures caused by the support pillars HR.

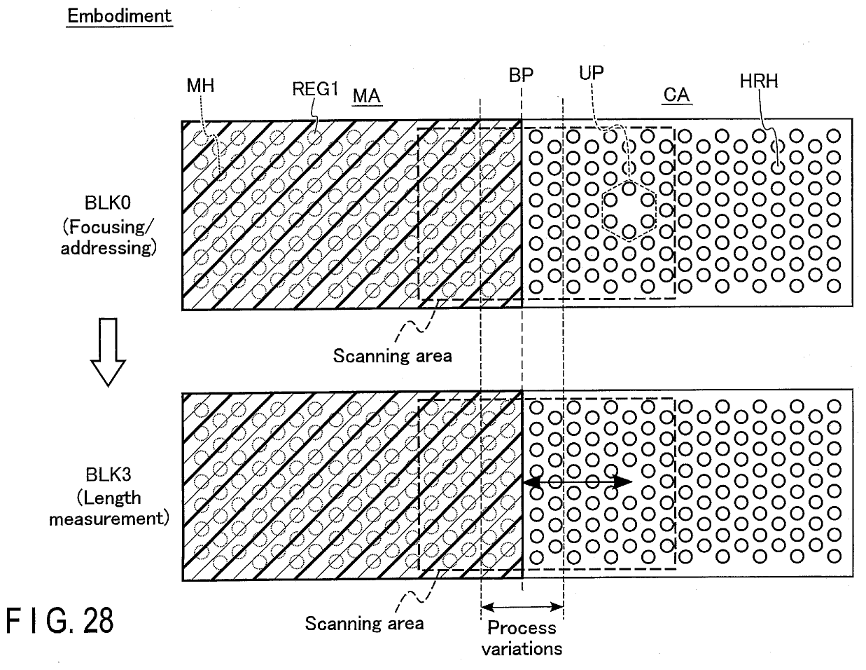

On the other hand, the semiconductor memory device 1 according to the embodiment includes, in the vicinity of the boundary portion BP, unique patterns UP in which some of the holes HRH that are periodically arranged are omitted. FIG. 28 is a schematic diagram showing an example of a length measurement method in a manufacturing process of the semiconductor memory device 1 according to the embodiment, and illustrates an area similar to that in FIG. 27.

As shown in FIG. 28, in the manufacturing process of the semiconductor memory device 1 according to the embodiment, a unique pattern UP is used as an anchor pattern of the focusing process and the addressing process at the time of the length measurement when a mask REG1 that covers a plurality of holes MH is formed by the process at step S13. The unique pattern UP clarifies the positional relationship between the holes HRH that are periodically arranged and the boundary portion BP. That is, the measurement device is capable of precisely recognizing the anchor pattern using the unique pattern UP that is not affected by process variations.

It is thereby possible in the semiconductor memory device 1 according to the embodiment to improve the precision of measurement of the boundary portion BP. Consequently, the semiconductor memory device 1 according to the embodiment is capable of suppressing occurrence of defects due to erroneous length measurement of the mask REG1, thereby improving the yield of the semiconductor memory device 1.

In the semiconductor memory device 1 according to the embodiment, the above-described unique pattern UP is arranged for each block BLK. Thus, the measurement device is capable of performing length measurement of a plurality of points along the Y direction, at the time of measurement of the boundary portion BP of the mask REG1. This allows the user to obtain multiple measurement results of the boundary portion BP of the mask REG1, and to obtain measurement results with higher reliability by performing equalization, etc. of the measurement results.

### [4] Modifications of Embodiment

The semiconductor memory device 1 according to the embodiment described above may be variously modified. Hereinafter, matters different from the semiconductor memory device 1 according to the embodiment will be described, in the order of a first modification, a second modification, a third modification, and a fourth modification.

[4-1] First Modification

A first modification of the embodiment relates to arrangement of a unique pattern UP. In a semiconductor memory device 1 according to the first modification of the embodiment, a memory cell array 10 further includes a dummy block DBLK that is adjacent to a block BLK in the Y direction. In the dummy block DBLK, for example, periodically arranged support pillars HR are provided, in place of the memory pillars MP.

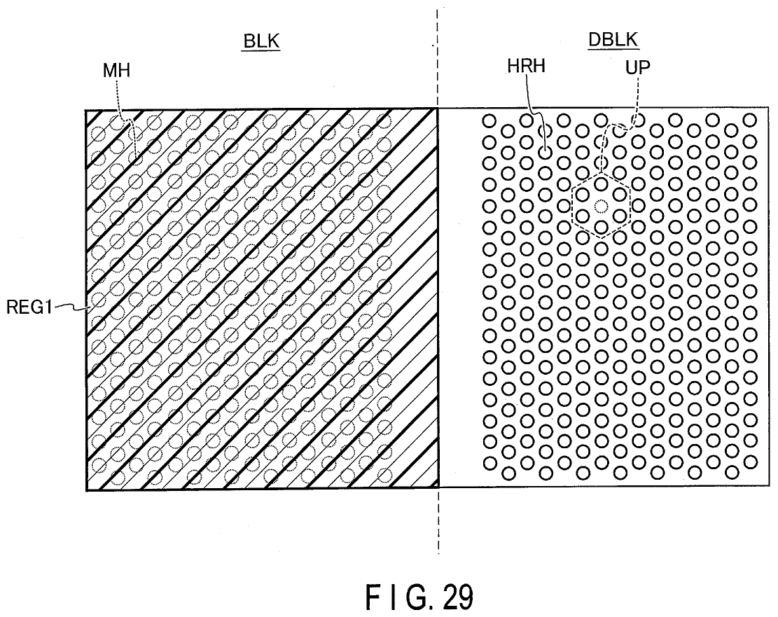

FIG. 29 shows an example of a planar layout of the memory cell array 10 included in the semiconductor memory device 1 according to the first modification of the embodiment, illustrating an area of a block BLK and a dummy block DBLK that are adjacent to each other. FIG. 29 corresponds to a state in which a mask REG is formed by the process at step S13 of the embodiment. As shown in FIG. 29, a plurality of holes HRH may be arranged, for example, instead of the holes MH, in the dummy block DBLK.

In the semiconductor memory device 1 according to a first modification of the embodiment, the holes HRH in the dummy block DBLK include a unique pattern UP that is similar to that of the embodiment. In other words, in the dummy block DBLK, a plurality of holes HRH are periodically arranged, and some of the holes HRH are omitted. The other configuration of the semiconductor memory device 1 according to the first modification of the embodiment is the same as that of the embodiment.

In the manufacturing process of the semiconductor memory device 1 according to the first modification of the embodiment, different materials are embedded in the holes MH in the block BLK and the holes HRH in the dummy block DBLK. That is, in the semiconductor memory device 1 according to the first modification of the embodiment, it is preferable that, in the process at step S13, the boundary position of the mask REG at the boundary portion between the block BLK and the dummy block DBLK also be managed.

In the manufacturing method of the semiconductor memory device 1 according to the first modification of the embodiment, when a mask REG1 that covers one of the block BLK and the dummy block DBLK is formed by the process at step S13, a unique pattern UP in the dummy block DBLK that is the same as that of the embodiment is used as an anchor pattern at the time of the length measurement.

It is thereby possible in the semiconductor memory device 1 according to the first modification of the embodiment to improve the precision of measurement of the boundary position between the block BLK and the dummy block DBLK, similarly to the embodiment. Consequently, the semiconductor memory device 1 according to the first modification of the embodiment is capable of suppressing occurrence of defects due to erroneous length measurement of the mask REG1, thereby improving the yield of the semiconductor memory device 1, similarly to the embodiment.

The unique pattern UP need not be arranged in the dummy block DBLK or the contact area CA. The unique pattern UP may be used in a manner similar to the embodiment at the time of management of a boundary position between an area in which a plurality of first holes are provided and an area in which a plurality of second holes in which members different from that of the first holes are embedded.

[4-2] Second Modification

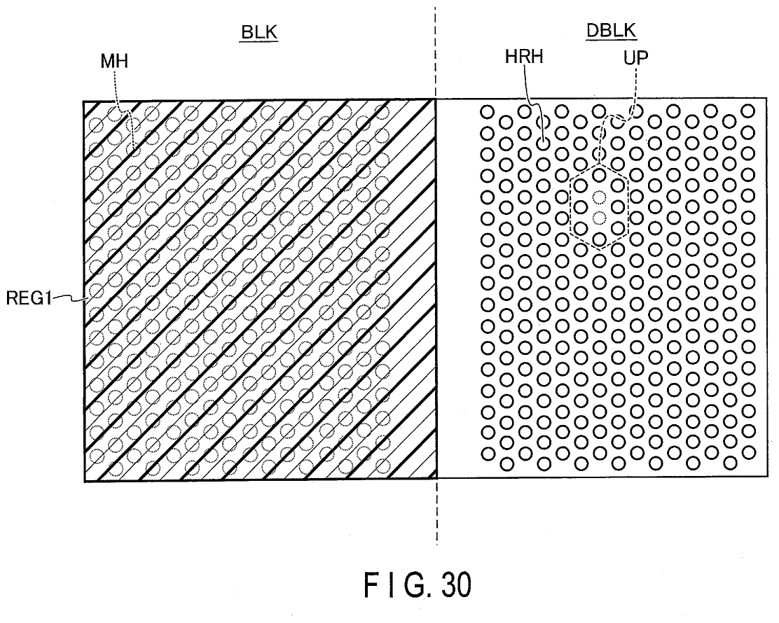

A second modification of the embodiment relates to a configuration of a unique pattern UP. FIG. 30 shows an example of a planar layout of the memory cell array 10 included in the semiconductor memory device 1 according to the second modification of the embodiment, illustrating an area and a state similar to those of FIG. 29. As shown in FIG. 30, in the second modification of the embodiment, the configuration of the unique pattern UP is different from that of the embodiment.

Specifically, the unique pattern UP according to the second modification of the embodiment is configured of eight holes HRH that are arranged in a hexagonal shape that is elongated in a single direction, with two support pillars HR omitted at a portion surrounded by the eight holes HRH. In other words, in the second modification of the embodiment, a portion at which two consecutive holes HRH are omitted, of a plurality of holes HRH (i.e., support pillars HR) that are periodically arranged, is used as a unique pattern UP. The other configuration of the semiconductor memory device 1 according to the second modification of the embodiment is the same as that of the embodiment.

The unique pattern UP according to the second modification of the embodiment described above may be used as an anchor pattern at the time of the length measurement, similarly to the embodiment. Accordingly, the semiconductor memory device 1 according to the second modification of the embodiment is capable of achieving an advantageous effect similar to that of the embodiment.

The configuration of the unique pattern UP is not limited to the configuration described in the embodiment or the second modification of the embodiment. The unique pattern UP needs to be configured by omission of at least one support pillar HR from a plurality of support pillars HR that are periodically arranged. When a plurality of support pillars HR are arranged in a lattice pattern, the periodical arrangement of the support pillars HR includes four support pillars HR that are arranged at vertex portions of a rectangular shape, and at least one support pillar HR in an area surrounded by the four support pillars HR may be omitted. In other words, the unique pattern UP suffices to be configured in such a manner that at least one support pillar HR is omitted, of a plurality of support pillars HR that are respectively arranged at vertexes of a polygonal shape, in an area surrounded by the support pillars HR. The number and arrangement of the support pillars HR that are omitted to configure a unique pattern UP may be freely designed if a three-dimensional structure at that portion may be maintained in the replacement process of the stacked interconnects.

[4-3] Third Modification

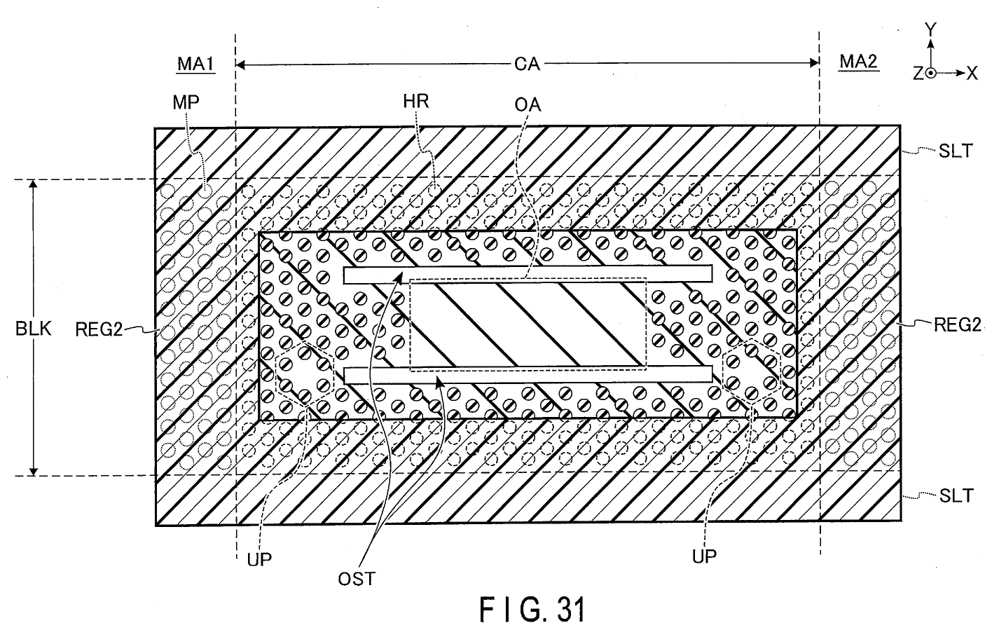

A third modification of the embodiment relates to arrangement of a unique pattern UP. FIG. 31 shows an example of a planar layout of a memory cell array 10 included in a semiconductor memory device 1 according to the third modification of the embodiment, illustrating an area and a state similar to those of FIG. 21. As shown in FIG. 31, in the third modification of the embodiment, the arrangement of a unique pattern UP and the shape of a mask REG2 are different from those of the embodiment.

Specifically, the unique pattern UP according to the third modification of the embodiment is suitably arranged in the vicinity of a slit OST. The unique pattern UP is, for example, arranged so as to be adjacent, in the X direction, to one of the slits OST that are adjacent to each other in the Y direction. When a mask REG2 is formed by, for example, a process at step S16, the unique patterns UP are arranged at an opening portion of the mask REG2.

In this example, the unique patterns UP are arranged on both sides of one of the slits OST in the X direction; however, at least one unique pattern UP may be arranged in the opening portion of the mask REG2. The number and arrangement of the unique patterns UP that are arranged in the opening portion of the mask REG2 is not limited to the example shown in FIG. 31, and may be suitably varied. The other configuration of the semiconductor memory device 1 according to the third modification of the embodiment is the same as that of the embodiment.

In the semiconductor memory device 1 according to the third modification of the embodiment described above, the positional relationship between the slit OST and the mask REG2 formed by the process at step S16, for example, is managed. In this length measurement, the measurement device uses the unique patterns UP arranged at the opening portion of the mask REG2 as anchor patterns.

Consequently, it is possible in the semiconductor memory device 1 according to the third modification of the embodiment to improve the precision of measurement of the mask position in a process (step S16) of integrally forming the slits SLT and OST and embedding members in different steps. Accordingly, the semiconductor memory device 1 according to the third modification of the embodiment is capable of suppressing occurrence of defects relating to slits OST that may occur by erroneous length measurement, thereby improving the yield of the semiconductor memory device 1.

[4-4] Fourth Modification

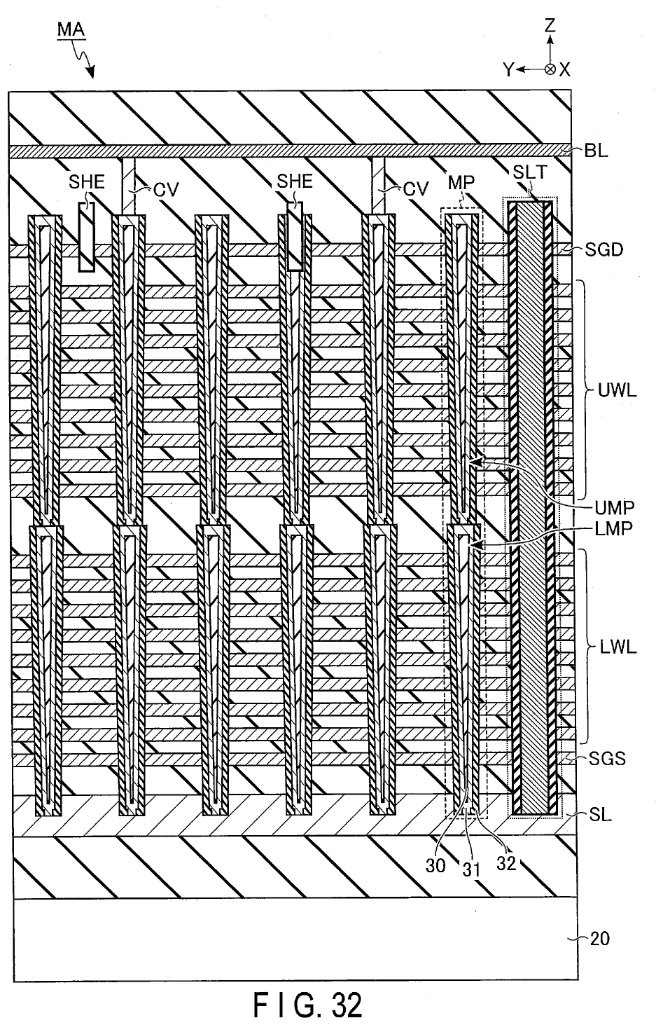

A fourth modification of the embodiment relates to a structure of a memory pillar MP. FIG. 32 shows an example of a cross-sectional structure of the memory cell array 10 included in the semiconductor memory device 1 according to the fourth modification of the embodiment, illustrating an area similar to that of FIG. 5. As shown in FIG. 32, the memory pillar MP according to the fourth modification of the embodiment has a structure in which a plurality of pillars LMP and UMP are coupled in the Z direction.

Specifically, the memory cell array 10 in the fourth modification of the embodiment includes a plurality of word lines LWL and a plurality of word lines UWL. The memory pillar MP in the fourth modification of the embodiment includes a lower pillar LMP and an upper pillar UMP. Each of the lower pillar LMP and the upper pillar UMP has a structure similar to that of the memory pillar MP of the embodiment.

The lower pillar LMP penetrates a plurality of word lines LWL and a select gate line SGS. The upper pillar UMP is provided above the lower pillar LMP, and penetrates a plurality of word lines UWL and a select gate line SGD. A semiconductor layer 31 of the lower pillar LMP is coupled to a source line SL. A bottom portion of the semiconductor layer 31 of the upper pillar UMP is coupled to an upper portion of the semiconductor layer 31 of the lower pillar LMP. An upper portion of the semiconductor layer 31 of the upper pillar UMP is coupled to a bit line BL via a contact CV.

A distance between the topmost word line LWL and the bottommost word line UWL in the Z direction is greater than a distance between adjacent word lines LWL in the Z direction, and greater than a distance between adjacent word lines UWL in the Z direction. A slit SLT splits, for example, the select gate lines SGD and SGS and the word lines LWL and UWL.

Each of an intersecting portion between the lower pillar LMP and the word line LWL and an intersecting portion between the upper pillar UMP and the word line UWL functions as a memory cell transistor MT. The lower pillar LMP and the upper pillar UMP need not be directly coupled, and an intermediate structure for coupling the lower pillar LMP and the upper pillar UMP may be provided. The other configuration of the semiconductor memory device 1 according to the fourth modification of the embodiment is the same as that of the embodiment.

In the semiconductor memory device 1 according to the fourth modification of the embodiment, since the memory pillar MP is configured of a plurality of pillars LMP and UMP, the number of word lines WL that are stacked can be increased, resulting in an increase in the storage capacity. In this case, the support pillars HR have, for example, an outer shape similar to that of the memory pillars MP, and have a structure in which the inside of each is embedded with an insulator. Even in this case, a unique pattern UP may be configured using the support pillars HR.

Thereby, the semiconductor memory device 1 according to the fourth modification of the embodiment is capable of using a unique pattern UP that uses support pillars HR as anchor patterns at the time of length measurement, similarly to the embodiment. Consequently, the semiconductor memory device 1 according to the fourth modification of the embodiment is capable of suppressing occurrence of defects due to erroneous length measurement at the time of formation of the mask REGI, thereby improving the yield of the semiconductor memory device 1.

### [5] Others

A semiconductor memory device according to an embodiment includes a substrate, a plurality of first members, a plurality of first conductive layers, a plurality of first pillars, and a plurality of second pillars. The substrate includes a first area, a second area, and a plurality of block areas. The first area and the second area are arranged in a first direction. The block areas are provided to extend in the first direction. The block areas are arranged in a second direction intersecting the first direction. The plurality of first members are provided to extend in the first direction. Each of the first members is arranged at a boundary portion between the block areas. The plurality of first conductive layers are arranged in a third direction intersecting the first and second directions and provided to be separated from one another. The first conductive layers are split by the first members. The plurality of first pillars are provided in an area in which the first area and the block areas overlap, to penetrate the first conductive layers in the third direction. The plurality of second pillars are provided in an area in which the second area and the block areas overlap, to penetrate the first conductive layers in the third direction. The second area includes a first sub-area in which the second pillars are periodically arranged in an area that overlaps at least one block area in the block areas. In the first sub-area, at least one second pillar is omitted from the second pillars that are periodically arranged. It is thereby possible to improve the yield of the semiconductor memory device.

In the drawings used for illustration in the present embodiment, a case is shown, as an example, where the memory pillars MP and the support pillars HR have an equal diameter in the Z direction; however, the configuration is not limited thereto. The memory pillars MP and the support pillars HR may have a tapered or inverse-tapered shape, or may have a shape that bulges at the middle (bowing shape). Similarly, the slits SLT and SHE may have a tapered or inverse-tapered shape, or may have a bowing shape. In the embodiment, a case has been described, as an example, where each of the memory pillars MP, the support pillars HR, and the contacts CC has a circular cross-sectional structure; however, the shape of the cross-sectional structure may be oval, or designed as any other shape.

In the embodiment, one or more types of insulators may be embedded in the slit SLT. In this case, a contact corresponding to the source line SL (conductive layer 21) is provided in the hookup area HA or the contact area CA. In the specification, the position of the slit SLT is specified based on the position of, for example, the contact LI. When the slit SLT is configured of an insulator, the position of the slit SLT may be specified by a seam in the slit SLT or a material that remains in the slit SLT at the time of the replacement process.

In the embodiment, a case has been described where the memory cell array 10 includes two hookup areas HA1 and HA2; however, the configuration is not limited thereto. In the memory cell array 10, at least one hookup area HA may be provided. In this case, the hookup area HA may be provided to be adjacent to the memory area MA, or may be provided in the middle of the memory area MA.

In the embodiment, a case has been described, as an example, where end portions of the word lines WL0 to WL7 in the hookup area HA are formed in a staircase shape that includes steps only in the X direction; however, the configuration is not limited thereto. For example, steps may be formed in the Y direction to provide terrace portions. The number of steps formed in the X and Y directions at end portions of the stacked word lines WL may be designed to be any number. That is, the end portions of the word lines WL in the hookup area HA in the semiconductor memory device 1 may be designed as a staircase shape with steps of any number of rows.

Herein, the term “couple” refers to electrical coupling, and does not exclude interposition of another component. Expressions such as “electrically coupled” cover insulator-interposed coupling that allows for the same operation as electrical coupling without an insulator. The term “pillar” refers to a structure provided in a hole formed in the manufacturing process of the semiconductor memory device 1. The expression “same-layer structure” refers to a structure in which at least the order of formation of layers is the same.

In the present specification, the term “area” may be regarded as a configuration included in the semiconductor substrate 20. When, for example, the semiconductor substrate 20 is defined as including memory areas MA1 and MA2, hookup areas HA1 and HA2, and a contact area CA, the memory areas MA1 and MA2, the hookup areas HA1 and HA2, and the contact area CA are respectively associated with different areas above the semiconductor substrate 20. The “height” corresponds to, for example, a distance between the configuration to be measured and the semiconductor substrate 20 in the Z direction. For the reference for the “height”, a configuration different from the semiconductor substrate 20 may be used.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor memory device comprising:
a substrate including a first area, a second area, and a plurality of block areas, the first area and the second area being arranged in a first direction, the block areas being provided to extend in the first direction, and the block areas being arranged in a second direction intersecting the first direction;
a plurality of first members provided to extend in the first direction, each of the first members being arranged at a boundary portion between the block areas;
a plurality of first conductive layers arranged in a third direction intersecting the first and second directions and provided to be separated from one another, the first conductive layers being split by the first members;
a plurality of first pillars provided in an area in which the first area and the block areas overlap, to penetrate the first conductive layers in the third direction; and
a plurality of second pillars provided in an area in which the second area and the block areas overlap, to penetrate the first conductive layers in the third direction, wherein
the second area includes a first sub-area in which the second pillars are periodically arranged in an area that overlaps at least one block area in the block areas, and
in the first sub-area, at least one second pillar is omitted from the second pillars that are periodically arranged.

2. The device of claim 1, wherein
the second area includes the first sub-area in which at least one second pillar is omitted in each of areas that overlap the block areas respectively.

3. The device of claim 1, wherein
the first sub-area includes the second pillars that are arranged at respective vertexes of a polygonal shape, and
a second pillar is omitted in an area surrounded by the second pillars that are arranged at respective vertexes.

4. The device of claim 1, wherein
the first sub-area includes six second pillars that are arranged at respective vertexes of a hexagonal shape, and
a second pillar is omitted in an area surrounded by the six second pillars that are arranged at respective vertexes.

5. The device of claim 1, wherein
the first sub-area includes the second pillars that are arranged at respective vertexes of a polygonal shape, and
two consecutive second pillars are omitted in an area surrounded by the second pillars that are arranged at respective vertexes.

6. The device of claim 1, wherein
an area in which the second area and at least one block area in the block areas overlap includes a second sub-area that is different from the first sub-area,
the second sub-area includes a second member, a third member, a plurality of insulating layers, and a first contact, the second member and the third member being arranged in the second direction to be separated from the first members, each of the second member and the third member including a portion that extends in the first direction, the insulating layers being arranged between the second member and the third member in the second direction, the insulating layers being provided at a height identical to a height of the first conductive layers, and the first contact being provided to penetrate the insulating layers in the third direction, and
each of the second member and the third member extends in the third direction between the first conductive layers and the insulating layers.

7. The device of claim 6, wherein
a portion from which the at least one second pillar is omitted is adjacent to the second member.

8. The device of claim 6, wherein
the first contact is used for coupling of an interconnect between the substrate and the first conductive layers, and an interconnect above the first conductive layers.

9. The device of claim 1, wherein
the substrate further includes a dummy block area that is adjacent to the block areas in the second direction,
the first area includes, in an area that overlaps the dummy block area, a third sub-area in which a plurality of same-material pillars that contain a material identical to a material of the second pillars are periodically arranged, and
in the third sub-area, at least one same-material pillar is omitted from the same-material pillars that are periodically arranged.

10. The device of claim 1, further comprising:
a plurality of second conductive layers provided above the first conductive layers, the second conductive layers being arranged in the third direction and separated from one another, the second conductive layers being split by the first members;
a plurality of third pillars that are provided to penetrate the second conductive layers in the third direction, the third pillars being respectively coupled to the first pillars; and
a plurality of fourth pillars that are provided to penetrate the second conductive layers in the third direction, the fourth pillars being respectively coupled to the second pillars, wherein
a distance between a bottommost second conductive layer of the second conductive layers in the third direction and a topmost first conductive layer of the first conductive layers in the third direction is greater than a distance between adjacent first conductive layers in the third direction, and is greater than a distance between adjacent second conductive layers in the third direction.

11. The device of claim 1, wherein
a portion at which one of the first pillars and one of the first conductive layers intersect functions as a memory cell, and
the second pillars are configured of an insulator.

12. The device of claim 1, further comprising:
a plurality of second contacts; and
a plurality of fifth pillars, wherein
the substrate further includes a third area,
the first area is interposed between the second area and the third area in the first direction,
the second contacts are respectively coupled to the first conductive layers in the third area,
the fifth pillars are provided to penetrate at least one of the first conductive layers in the third area, and
the fifth pillars contain a material identical to a material of the second pillars.

13. The device of claim 1, further comprising:
a plurality of sixth pillars, wherein
the substrate further includes a fourth area,
the second area is interposed between the first area and the fourth area in the first direction,
the sixth pillars are provided in an area in which the fourth area and the block areas overlap, to penetrate the first conductive layers in the third direction, and
the sixth pillars contain a material identical to a material of the first pillars.

14. A semiconductor memory device comprising:
a substrate including a plurality of block areas and a dummy block area, the block areas being provided to extend in a first direction, the block areas being arranged in a second direction intersecting the first direction, and the dummy block area being adjacent to the block areas in the second direction;
a plurality of first members provided to extend in the first direction, the first members being respectively arranged at boundary portions between the block areas and the dummy block area;
a plurality of first conductive layers arranged in a third direction intersecting the first and second directions and provided to be separated from one another, the first conductive layers being split by the first members;
a plurality of first pillars provided in the block areas to penetrate the first conductive layers in the third direction; and
a plurality of second pillars provided in the dummy block area to penetrate the first conductive layers in the third direction, wherein
the dummy block area includes a sub-area in which the second pillars are periodically arranged, and
in the sub-area, at least one second pillar is omitted from the second pillars that are periodically arranged.

15. The device of claim 14, wherein
the sub-area includes the second pillars that are arranged at respective vertexes of a polygonal shape, and
a second pillar is omitted in an area surrounded by the second pillars that are arranged at respective vertexes.

16. The device of claim 14, wherein
the sub-area includes six second pillars that are arranged at respective vertexes of a hexagonal shape, and
a second pillar is omitted in an area surrounded by the six second pillars that are arranged at respective vertexes.

17. The device of claim 14, wherein
the sub-area includes the second pillars that are arranged at respective vertexes of a polygonal shape, and
two consecutive second pillars are omitted in an area surrounded by the second pillars that are arranged at respective vertexes.

18. The device of claim 14, further comprising:
a plurality of second conductive layers provided above the first conductive layers, the second conductive layers being arranged in the third direction and separated from one another, the second conductive layers being split by the first members;
a plurality of third pillars that are provided to penetrate the second conductive layers in the third direction, the third pillars being respectively coupled to the first pillars; and
a plurality of fourth pillars that are provided to penetrate the second conductive layers in the third direction, the fourth pillars being respectively coupled to the second pillars, wherein
a distance between a bottommost second conductive layer of the second conductive layers in the third direction and a topmost first conductive layer of the first conductive layers in the third direction is greater than a distance between adjacent first conductive layers in the third direction, and is greater than a distance between adjacent second conductive layers in the third direction.

19. The device of claim 14, wherein
a portion at which one of the first pillars and one of the first conductive layers intersect functions as a memory cell, and
the second pillars are configured of an insulator.

20. The device of claim 14, further comprising:
a plurality of same-material pillars containing a material identical to a material of the second pillars, the same-material pillars being provided to penetrate at least one of the first conductive layers in the block areas.
